(19) United States
(12) Patent Application Publication
(10) Pub. No.: US 2026/0188211 A1
(43) Pub. Date: Jul. 2, 2026

(54) Display Substrate, Drive Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Haigang QING, Beijing (CN); Gukhwan SONG, Beijing (CN); Ming HU, Beijing (CN); Haijun QIU, Beijing (CN)

(21) Appl. No.: 18/857,197

(22) PCT Filed: Nov. 21, 2023
(86) PCT No.: PCT/CN2023/132981

§ 371 Date: Oct. 16, 2024

(30) Foreign Application Priority Data
Sep. 25, 2023 (WO) PCT/CN2023/120988

(51) Int. Cl. G09G 3/3233; H10K 59/131

(52) U.S. Cl. CPC G09G 3/3233; H10K 59/131; G09G 2300/0426; G09G 2300/0819; G09G 2300/0842; G09G 2300/0861; G09G 2310/08; G09G 2320/0209; G09G 2320/0233; G09G 2320/0257; G09G 2330/021

(57) ABSTRACT

Disclosed are a display substrate and a drive method therefor, and a display apparatus. The display substrate includes a plurality of circuit units, and at least one circuit unit includes, at least, a pixel drive circuit and a light emitting signal line. In at least one circuit unit, a pixel drive circuit includes at least a third transistor, a fifth transistor, and a sixth transistor, a second electrode of the fifth transistor is connected with a first electrode of the third transistor, and a first electrode of the sixth transistor is connected with a second electrode of the third transistor. In at least one pixel drive circuit of at least one unit row, a fifth transistor is connected with a light emitting signal line in a previous unit row, and a sixth transistor is connected with a light emitting signal line in a current unit row.

### CROSS-REFERENCE TO RELATED APPLICATIONS

The present application is a U.S. National Phase Entry of International Application No. PCT/CN2023/132981 having an international filing date of Nov. 21, 2023, which claims the priority to the PCT Application No. PCT/CN2023/120988, filed on Sep. 25, 2023, contents of the above-identified applications should be regarded as being incorporated herein by reference.

### TECHNICAL FIELD

The present disclosure relates to, but is not limited to, the field of display technologies, and particularly to a display substrate and a drive method therefor, and a display apparatus.

### BACKGROUND

An Organic Light Emitting Diode (OLED) and a Quantum dot Light Emitting Diode (QLED) are active light emitting display devices and have advantages of self-illumination, a wide viewing angle, a high contrast ratio, low power consumption, an extremely high reaction speed, lightness and thinness, flexibility, and a low cost, etc. With continuous development of display technologies, a display apparatus in which an OLED or a QLED is used as a light emitting device and a Thin Film Transistor (TFT) is used for signal control has become a mainstream product in the field of display at present.

### SUMMARY

The following is a summary of subject matters described herein in detail. This summary is not intended to limit the protection scope of claims.

In one aspect, a display substrate is provided in the present disclosure, the display substrate includes a plurality of circuit units constituting a plurality of unit rows and a plurality of unit columns; at least one circuit unit includes, at least, a pixel drive circuit and a light emitting signal line, wherein the pixel drive circuit is configured to output a drive current to a connected light emitting device, and the light emitting signal line is configured to provide a light emitting control signal to the pixel drive circuit; in at least one circuit unit, the pixel drive circuit includes, at least, a third transistor acting as a drive transistor, a fifth transistor acting as a first light emitting control transistor, and a sixth transistor acting as a second light emitting control transistor; wherein a first electrode of the fifth transistor is connected with a first power supply line, a second electrode of the fifth transistor is connected with a first electrode of the third transistor, a first electrode of the sixth transistor is connected with a second electrode of the third transistor, and a second electrode of the sixth transistor is connected with the light emitting device; in at least one pixel drive circuit of at least one unit row, the fifth transistor is connected with the light emitting signal line in a previous unit row, and the sixth transistor is connected with the light emitting signal line in a current unit row.

In an exemplary implementation mode, in at least one pixel drive circuit, the fifth transistor and the sixth transistor are disposed on both sides of the third transistor in a unit column direction, respectively.

In an exemplary implementation mode, the fifth transistor includes, at least, a fifth active layer, and the sixth transistor includes, at least, a sixth active layer; in at least one pixel drive circuit of at least one unit row, the fifth active layer is disposed in a circuit unit of the previous unit row, and the sixth active layer is disposed in a circuit unit of the current unit row.

In an exemplary implementation mode, in at least one pixel drive circuit of at least one unit row, the fifth active layer is disposed on a side of the sixth active layer of the pixel drive circuit in the previous unit row in a unit row direction.

In an exemplary implementation mode, the pixel drive circuit further includes a storage capacitor and a power supply connection electrode, the storage capacitor includes a first electrode plate and a second electrode plate, an orthographic projection of the first electrode plate on a plane of the display substrate is overlapped, at least partially, with an orthographic projection of the second electrode plate on the plane of the display substrate; in at least one pixel drive circuit of at least one unit row, a first end of the power supply connection electrode is connected with a first region of the fifth active layer of the pixel drive circuit in a next unit row, and a second end of the power supply connection electrode is connected with the second electrode plate of the pixel drive circuit in the current unit row.

In an exemplary implementation mode, at least one circuit unit further includes a scan signal line configured to provide a scan signal to the pixel drive circuit. The pixel drive circuit further includes a fourth transistor acting as a data writing transistor and a seventh transistor acting as a second initialization transistor, a first electrode of the fourth transistor is connected with a data signal line, a second electrode of the fourth transistor is connected with a first electrode of the third transistor, a first electrode of the seventh transistor is connected with a second initial signal line, and a second electrode of the seventh transistor is connected with a second electrode of the sixth transistor. In at least one pixel drive circuit of at least one unit row, the fourth transistor is connected with the scan signal line in the previous unit row, and the seventh transistor is connected with the scan signal line in the current unit row.

In an exemplary implementation mode, in at least one pixel drive circuit, the fourth transistor and the seventh transistor are disposed on both sides of the third transistor in a unit column direction, respectively.

In an exemplary implementation mode, the fourth transistor includes, at least, a fourth active layer, and the seventh transistor includes, at least, a seventh active layer; in at least one pixel drive circuit of at least one unit row, the fourth active layer is disposed in a circuit unit in the previous unit row, and the seventh active layer is disposed in a circuit unit of the current unit row.

In an exemplary implementation mode, in at least one pixel drive circuit of at least one unit row, the fourth active layer is disposed on a side of the seventh active layer of the pixel drive circuit in the previous unit row in a unit row direction.

In an exemplary implementation mode, the pixel drive circuit further includes a first transistor acting as a first initialization transistor, a second transistor acting as a compensation transistor, a fourth transistor acting as a data writing transistor, and a seventh transistor acting as a second initialization transistor, wherein a first electrode of the first transistor is connected with a first initial signal line, a first electrode of the fourth transistor connected with a data signal line, a first electrode of the seventh transistor is connected with a second initial signal line, a second electrode of the first transistor and a first electrode of the second transistor are connected with a gate electrode of the third transistor through a first node electrode, and a first electrode of the third transistor, a second electrode of the fourth transistor, and a second electrode of the fifth transistor are connected with each other through a second node electrode.

In an exemplary implementation mode, an orthographic projection of the first power supply line on a plane of the display substrate is overlapped, at least partially, with an orthographic projection of the first node electrode on the plane of the display substrate.

In an exemplary implementation mode, an orthographic projection of the second node electrode on a plane of the display substrate is overlapped, at least partially, with an orthographic projection of the first initial signal line on the plane of the display substrate, and/or, the orthographic projection of the second node electrode on the plane of the display substrate is overlapped, at least partially, with an orthographic projection of the second initial signal line on the plane of the display substrate.

In an exemplary implementation mode, a gate electrode of the first transistor is connected with a fourth scan signal line, and an orthographic projection of the second node electrode on a plane of the display substrate is overlapped, at least partially, with an orthographic projection of the fourth scan signal line on the plane of the display substrate.

In an exemplary implementation mode, a gate electrode of the second transistor is connected with a third scan signal line, and an orthographic projection of the second node electrode on a plane of the display substrate is overlapped, at least partially, with an orthographic projection of the third scan signal line on the plane of the display substrate.

In an exemplary implementation mode, the first initial signal line is connected with a first shield electrode, an orthographic projection of the first shield electrode on a plane of the display substrate is overlapped, at least partially, with an orthographic projection of a node between two gate electrodes in the second transistor on the plane of the display substrate.

In an exemplary implementation mode, the second initial signal line is connected with a second shield electrode, and an orthographic projection of the second shield electrode on a plane of the display substrate is overlapped, at least partially, with an orthographic projection of a node between two gate electrodes in the first transistor on the plane of the display substrate.

In another aspect, a display apparatus is also provided in the present disclosure, and the display apparatus includes the display substrate described above.

In yet another aspect, a drive method of a display substrate is also provided in the present disclosure, the display substrate includes a plurality of circuit units constituting a plurality of unit rows and a plurality of unit columns; at least one circuit unit includes, at least, a pixel drive circuit and a light emitting signal line, wherein the pixel drive circuit is configured to output a drive current to a connected light emitting device, and the light emitting signal line is configured to provide a light emitting control signal to the pixel drive circuit; in at least one circuit unit, the pixel drive circuit includes, at least, a third transistor acting as a drive transistor, a fifth transistor acting as a first light emitting control transistor, and a sixth transistor acting as a second light emitting control transistor; a first electrode of the fifth transistor is connected with a first power supply line, a second electrode of the fifth transistor is connected with a first electrode of the third transistor, a first electrode of the sixth transistor is connected with a second electrode of the third transistor, and a second electrode of the sixth transistor is connected with the light emitting device; the drive method includes, at least, a light emitting stage in which, in at least one pixel drive circuit of at least one unit row, turn-on and turn-off of the fifth transistor is controlled by the light emitting signal line in a previous unit row, and turn-on and turn-off of the sixth transistor is controlled by the light emitting signal line in a current unit row.

In an exemplary implementation mode, at least one circuit unit further includes a scan signal line configured to provide a scan signal to the pixel drive circuit. The pixel drive circuit further includes a fourth transistor as a data writing transistor and a seventh transistor as a second initialization transistor, a first electrode of the fourth transistor is connected with a data signal line, a second electrode of the fourth transistor is connected with a first electrode of the third transistor, a first electrode of the seventh transistor is connected with a second initial signal line, and a second electrode of the seventh transistor is connected with a second electrode of the sixth transistor. The drive method further includes a data writing stage and a reset stage. In at least one pixel drive circuit of at least one unit row, turn-on and turn-off of the fourth transistor is controlled by the scan signal line in the previous unit row in the data writing stage, and turn-on and turn-off of the seventh transistor is controlled by the scan signal line in the current unit row in the reset stage.

Other aspects may be comprehended after drawings and detailed description are read and understood.

### BRIEF DESCRIPTION OF DRAWINGS

Accompany drawings are used to provide understanding of technical solutions of the present disclosure, and form a part of the specification. The accompany drawings and embodiments of the present disclosure are adopted to explain the technical solutions of the present disclosure, and do not form limitations on the technical solutions of the present disclosure.

FIG. 1 is a schematic diagram of a structure of a display apparatus.

FIG. 2 is a schematic diagram of a planar structure of a display substrate.

FIG. 3 is a schematic diagram of a sectional structure of a display substrate.

FIG. 4 is an equivalent circuit diagram of a pixel drive circuit according to an exemplary embodiment of the present disclosure.

FIG. 5 is a drive timing diagram of the pixel drive circuit shown in FIG. 4.

FIG. 6 is an equivalent circuit diagram of cascaded pixel drive circuits according to an exemplary embodiment of the present disclosure.

FIG. 7 is a schematic diagram of a planar structure of a display substrate according to an exemplary embodiment of the present disclosure.

FIG. 8 is a schematic diagram of a display substrate after a pattern of a semiconductor layer is formed, according to the present disclosure.

FIGS. 9A and 9B are schematic diagrams of a display substrate after a pattern of a first conductive layer is formed, according to the present disclosure.

FIGS. 10A and 10B are schematic diagrams of a display substrate after a pattern of a second conductive layer is formed, according to the present disclosure.

FIG. 11 is a schematic diagram of a display substrate after a pattern of a fourth insulation layer is formed, according to the present disclosure.

FIGS. 12A and 12B are schematic diagrams of a display substrate after a pattern of a third conductive layer is formed, according to the present disclosure.

FIG. 13 is a schematic diagram of a display substrate after a pattern of a first planarization layer is formed, according to the present disclosure.

FIGS. 14A and 14B are schematic diagrams of a display substrate after a pattern of a fourth conductive layer is formed, according to the present disclosure.

Reference numbers are described as follows.

| | | |
|---|---|---|
| 11-first active layer; | 12-second active layer; | 13-third active layer; |
| 14-fourth active layer; | 15-fifth active layer; | 16-sixth active layer; |
| 17-seventh active layer; | 21-first scan signal line; | 22-second scan signal line |
| 23-third scan signal line; | 24-fourth scan signal line; | 25-first light emitting signal |
| 26-second light emitting | 31-first electrode plate; | line; |
| signal line; | 34-electrode plate connection | 32-second electrode plate; |
| 33-opening; | block; | 41-first initial signal line; |
| 42-second initial signal line; | 43-first shield electrode; | 44-second shield electrode; |
| 51-first connection electrode; | 52-second connection | 53-third connection electrode; |
| 54-fourth connection | electrode; | 56-sixth connection electrode; |
| electrode; | 55-fifth connection electrode; | 62-data signal line; |
| 57-seventh connection | 61-first power supply line; | 102-drive circuit layer; |
| electrode; | 101-base substrate; | |
| 63-anode connection | 104-encapsulation structure | |
| electrode; | layer. | |
| 103-light emitting structure | | |
| layer; | | |

### DETAILED DESCRIPTION

To make objectives, technical solutions, and advantages of the present disclosure clearer, the embodiments of the present disclosure will be described in detail below with reference to the accompany drawings. It is to be noted that implementation modes may be implemented in multiple different forms. Those of ordinary skills in the art may easily understand such a fact that modes and contents may be transformed into various forms without departing from the purpose and scope of the present disclosure. Therefore, the present disclosure should not be explained as being limited to contents recorded in following implementation modes only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements with reference to the drawings, not to indicate or imply that a referred apparatus or element must have a specific orientation and be structured and operated with the specific orientation but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element with a certain electrical action. An “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

In the present disclosure, “about” refers to that a boundary is not defined so strictly and numerical values within a range of process and measurement errors are allowed.

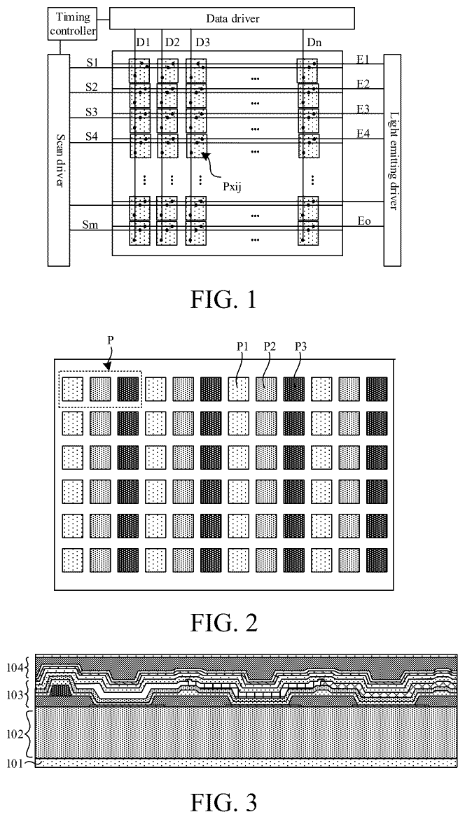

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively. The data driver is connected with a plurality of data signal lines (D1 to Dn), respectively. The scan driver is connected with a plurality of scan signal lines (S1 to Sm) respectively. The light emitting driver is connected with a plurality of light emitting signal lines (E1 to Eo), respectively. The pixel array may include a plurality of sub-pixels Pxij, wherein i and j may be natural numbers. At least one sub-pixel Pxij may include a circuit unit and a light emitting unit, wherein the circuit unit may include, at least, a pixel drive circuit connected with a scan signal line, a light emitting signal line, and a data signal line, respectively. The light emitting unit may include a light emitting device connected with the pixel drive circuit of the circuit unit. In an exemplary implementation mode, the timing controller may provide the data driver with a grayscale value and a control signal which are suitable for a specification of the data driver, provide the scan driver with a clock signal and a scan start signal and the like which are suitable for a specification of the scan driver, and provide the light emitting driver with a clock signal and an emission stop signal and the like which are suitable for a specification of the light emitting driver. The data driver may generate data voltages to be provided to the data signal lines D1, D2, D3, . . . , and Dn, using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signal to be provided to the scan signal lines S1, S2, S3, . . . , and Sm by receiving the clock signal and the scan start signal and the like from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation mode, the pixel array may be disposed on a display substrate.

FIG. 2 is a schematic diagram of a planar structure of a display substrate. As shown in FIG. 2, the display substrate may include a plurality of pixel units P arranged in a matrix, and at least one of the pixel units P may include a first sub-pixel P1, a second sub-pixel P2, and a third sub-pixel P3. Each sub-pixel may include a circuit unit and a light emitting unit. The circuit unit may at least include a pixel drive circuit, the pixel drive circuit is connected with a scan signal line, a data signal line, and a light emitting signal line respectively, and is configured to receive a data voltage transmitted by the data signal line and output a corresponding current to the light emitting unit under control of the scan signal line and the light emitting signal line. The light emitting unit may include a light emitting device connected with a pixel drive circuit of a sub-pixel where the light emitting device is located, and the light emitting device is configured to emit light with corresponding brightness in response to a current output by the pixel drive circuit of the sub-pixel where the light emitting device is located.

In an exemplary implementation mode, the first sub-pixels P1 may be red sub-pixels (R) emitting red light, the second sub-pixels P2 may be green sub-pixels (G) emitting green light, and the third sub-pixels P3 may be blue sub-pixels (B) emitting blue light. In an exemplary implementation mode, a sub-pixel may be in a shape of a rectangle, a rhombus, a pentagon, or a hexagon. Three sub-pixels may be arranged in a manner to stand side by side horizontally, in a manner to stand side by side vertically, or in a delta-shaped arrangement, etc., which is not limited here in the present disclosure.

In an exemplary implementation mode, a pixel unit may include four sub-pixels, and the four sub-pixels may be arranged in a manner to stand side by side horizontally, in a manner to stand side by side vertically, or in a manner of a square, which is not limited here in the present disclosure.

FIG. 3 is a schematic diagram of a sectional structure of a display substrate, illustrating a structure of three sub-pixels in a display region. As shown in FIG. 3, on a plane perpendicular to the display substrate, the display substrate may include a drive circuit layer 102 disposed on a base substrate 101, a light emitting structure layer 103 disposed on a side of the drive circuit layer 102 away from the base substrate 101, and an encapsulation structure layer 104 disposed on a side of the light emitting structure layer 103 away from the base substrate 101. In some possible implementation modes, the display substrate may include another film layer, such as a touch structure layer, which is not limited here in the present disclosure.

In an exemplary implementation mode, the base substrate 101 may be a flexible base substrate, or may be a rigid base substrate. The drive circuit layer 102 may include a plurality of circuit units, each of which may at least include a pixel drive circuit composed of a plurality of transistors and a storage capacitor. The light emitting structure layer 103 may include a plurality of light emitting units, each light emitting unit may include a light emitting device, and the light emitting device may include, at least, an anode, an organic emitting layer, and a cathode. The anode is connected with the pixel drive circuit. The organic emitting layer is connected with the anode. The cathode is connected with the organic emitting layer. The organic emitting layer emits light of a corresponding color under drive of the anode and the cathode. The encapsulation structure layer 104 may include a first encapsulation structure layer, a second encapsulation structure layer, and a third encapsulation structure layer that are stacked. The first encapsulation structure layer and the third encapsulation structure layer may be made of an inorganic material, the second encapsulation structure layer may be made of an organic material, and the second encapsulation structure layer is disposed between the first encapsulation structure layer and the third encapsulation structure layer to form a laminated structure of inorganic material/organic material/inorganic material and ensure that external moisture cannot enter the light emitting structure layer 103.

A display substrate is provided in an exemplary embodiment of the present disclosure. In an exemplary implementation mode, on a plane perpendicular to the display substrate, the display substrate may include a drive structure layer disposed on a base substrate and a light emitting structure layer disposed on a side of the drive structure layer away from the base substrate. On a plane parallel to the display substrate, the drive structure layer may include a plurality of circuit units constituting a plurality of unit rows and a plurality of unit columns, and at least one of the circuit units may include a pixel drive circuit configured to output a corresponding current to a light emitting device connected with the pixel drive circuit. The light emitting structure layer may include a plurality of light emitting units, at least one of the light emitting units may include a light emitting device connected with a pixel drive circuit of a corresponding circuit unit. The light emitting device is configured to emit light with corresponding brightness in response to a current output by a pixel drive circuit connected with the light emitting device.

In an exemplary implementation mode, circuit units mentioned in the present disclosure refer to regions divided according to pixel drive circuits, and light emitting units mentioned in the present disclosure refer to regions divided according to light emitting devices. In an exemplary implementation mode, a position and a shape of an orthographic projection of a light emitting unit on the base substrate may correspond to a position and a shape of an orthographic projection of a circuit unit on the base substrate, or a position and a shape of an orthographic projection of a light emitting unit on the base substrate may not correspond to a position and a shape of an orthographic projection of a circuit unit on the base substrate.

In an exemplary implementation mode, the display substrate in the present disclosure may include a plurality of circuit units constituting a plurality of unit rows and a plurality of unit columns. At least one circuit unit includes, at least, a pixel drive circuit and a light emitting signal line, the pixel drive circuit is configured to output a drive current to a connected light emitting device, and the light emitting signal line is configured to provide a light emitting control signal to the pixel drive circuit. In at least one circuit unit, the pixel drive circuit includes, at least, a third transistor acting as a drive transistor, a fifth transistor acting as a first light emitting control transistor, and a sixth transistor acting as a second light emitting control transistor. A first electrode of the fifth transistor is connected with a first power supply line, a second electrode of the fifth transistor is connected with a first electrode of the third transistor, a first electrode of the sixth transistor is connected with a second electrode of the third transistor, and a second electrode of the sixth transistor is connected with the light emitting device. In at least one pixel drive circuit of at least one unit row, the fifth transistor is connected with a light emitting signal line in a previous unit row, and the sixth transistor is connected with a light emitting signal line in a current unit row.

In an exemplary implementation mode, at least one circuit unit further includes a scan signal line configured to provide a scan signal to the pixel drive circuit. The pixel drive circuit further includes a fourth transistor acting as a data writing transistor and a seventh transistor acting as a second initialization transistor, a first electrode of the fourth transistor is connected with a data signal line, a second electrode of the fourth transistor is connected with a first electrode of the third transistor, a first electrode of the seventh transistor is connected with a second initial signal line, and a second electrode of the seventh transistor is connected with a second electrode of the sixth transistor. In at least one pixel drive circuit of at least one unit row, the fourth transistor is connected with a scan signal line in a previous unit row, and the seventh transistor is connected with a scan signal line in a current unit row.

A display substrate according to an exemplary embodiment of the present disclosure is illustrated below through some examples.

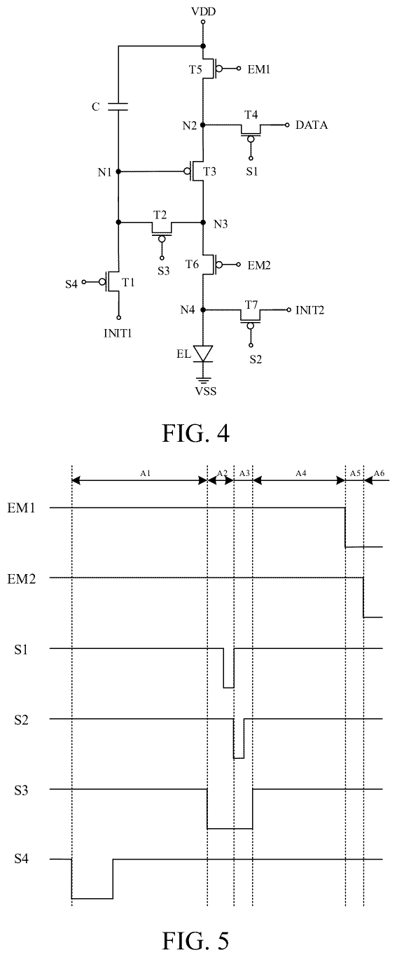

FIG. 4 is an equivalent circuit diagram of a pixel drive circuit according to an exemplary embodiment of the present disclosure. As shown in FIG. 4, the pixel drive circuit may be of a 7T1C structure, and may include seven transistors (a first transistor T1 to a seventh transistor T7) and one storage capacitor C. Each pixel drive circuit is connected with 10 signal lines (a first scan signal line S1, a second scan signal line S2, a third scan signal line S3, a fourth scan signal line S4, a first light emitting signal line EM1, a second light emitting signal line EM2, a first initial signal line INIT1, a second initial signal line INIT2, a data signal line DATA, and a first power supply line VDD), respectively.

In an exemplary implementation mode, each pixel drive circuit may include a first node N1, a second node N2, a third node N3, and a fourth node N4. The first node N1 is connected with a second electrode of the first transistor T1, a first electrode of the second transistor T2, a gate electrode of the third transistor T3, and a first end of the storage capacitor C, respectively. The second node N2 is connected with a first electrode of the third transistor T3, a second electrode of the fourth transistor T4, and a second electrode of the fifth transistor T5, respectively. The third node N3 is connected with a second electrode of the second transistor T2, a second electrode of the third transistor T3, and a first electrode of the sixth transistor T6, respectively. The fourth node N4 is connected with a second electrode of the sixth transistor T6 and a second electrode of the seventh transistor T7, respectively.

In an exemplary implementation mode, the first end of the storage capacitor C in the pixel drive circuit is connected with the first node N1, and a second end of the storage capacitor C is connected with the first power supply line VDD.

In an exemplary implementation mode, the first transistor T1 may be referred to as a first initialization transistor, a gate electrode of the first transistor T1 is connected with the fourth scan signal line S4, a first electrode of the first transistor T1 is connected with the first initial signal line INIT1, and a second electrode of the first transistor T1 is connected with the first node N1.

In an exemplary implementation mode, the second transistor T2 may be referred to as a compensation transistor, a gate electrode of the second transistor T2 is connected with the third scan signal line S3, the first electrode of the second transistor T2 is connected with the first node N1, and the second electrode of the second transistor T2 is connected with the third node N3.

In an exemplary implementation mode, the third transistor T3 may be referred to as a drive transistor, the gate electrode of the third transistor T3 is connected with the first node N1, the first electrode of the third transistor T3 is connected with the second node N2, and the second electrode of the third transistor T3 is connected with the third node N3.

In an exemplary implementation mode, the fourth transistor T4 may be referred to as a data writing transistor, a gate electrode of the fourth transistor T4 is connected with the first scan signal line S1, a first electrode of the fourth transistor T4 is connected with the data signal line DATA, and the second electrode of the fourth transistor T4 is connected with the second node N2.

In an exemplary implementation mode, the fifth transistor T5 may be referred to as a first light emitting control transistor, a gate electrode of the fifth transistor T5 is connected with the first light emitting signal line EM1, a first electrode of the fifth transistor T5 is connected with the first power supply line VDD, and the second electrode of the fifth transistor T5 is connected with the second node N2.

In an exemplary implementation mode, the sixth transistor T6 may be referred to as a second light emitting control transistor, the gate electrode of the sixth transistor T6 is connected with the second light emitting signal line EM2, the first electrode of the sixth transistor T6 is connected with the third node N3, and the second electrode of the sixth transistor T6 is connected with the fourth node N4.

In an exemplary implementation mode, the seventh transistor T7 may be referred to as a second initialization transistor, a gate electrode of the seventh transistor T7 is connected with the second scan signal line S2, a first electrode of the seventh transistor T7 is connected with the second initial signal line INIT2, and the second electrode of the seventh transistor T7 is connected with the fourth transistor N4.

In an exemplary implementation mode, a first electrode of a light emitting device EL is connected with the second node N4, and a second electrode of the light emitting device EL is connected with the second power supply line VSS. The light emitting device EL may be an OLED including a first electrode (anode), an organic emitting layer, and a second electrode (cathode) which are stacked, or may be a QLED including a first electrode, a quantum dot emitting layer, and a second electrode which are stacked.

In an exemplary implementation mode, a signal of the first power supply line VDD is a high-level signal continuously provided, and a signal of the second power supply line VSS is a low-level signal continuously provided.

In an exemplary implementation mode, the first transistor T1 to the second transistor T2, and the fourth transistor T4 to the seventh transistor T7 are switching transistors, and the third transistor T3 is a drive transistor.

In an exemplary implementation mode, the first transistor T1 to the seventh transistor T7 in the pixel drive circuit may be P-type transistors, or may be N-type transistors. In some other possible exemplary implementation modes, the first transistor T1 to the seventh transistor T7 in the pixel drive circuit may include a P-type transistor and an N-type transistor.

In an exemplary implementation mode, for the first transistor T1 to the seventh transistor T7 in the pixel drive circuit, low temperature poly silicon transistors may be adopted, or oxide transistors may be adopted, or a low temperature poly silicon transistor and an oxide transistor may be adopted. An active layer of a low temperature poly silicon transistor is made of Low Temperature Poly Silicon (LTPS), and an active layer of an oxide transistor is made of an oxide semiconductor (Oxide). The low temperature poly silicon transistor has advantages such as a high migration rate and fast charging, and the oxide transistor has advantages such as a low drain current. The low temperature poly silicon transistor and the oxide transistor are integrated on one display substrate to form a Low Temperature Polycrystalline Oxide (LTPO) display substrate, such that advantages of the low temperature poly silicon transistor and the oxide transistor may be utilized, low-frequency drive may be achieved, power consumption may be reduced, and display quality may be improved.

FIG. 5 is a drive timing diagram of the pixel drive circuit shown in FIG. 4. As shown in FIG. 5, in an exemplary implementation mode, an operating process of the pixel drive circuit may include following stages A1 to A6.

The first stage A1 may be referred to as a first node N1 reset stage. A signal of the fourth scan signal line S4 is a low-level signal, and signals of the first scan signal line S1, the second scan signal line S2, the third scan signal line S3, the first light emitting signal line EM1, and the second light emitting signal line EM2 are high-level signals, so that the first transistor T1 is turned on and the other switching transistors are turned off.

The first transistor T1 is turned on, so that a signal of the first initial signal line INIT1 is supplied to the first node N1 to initialize (reset) the first node N1, and original charges in the first node N1 is cleared.

The second stage A2 may be referred to as a data writing stage. Signals of the first scan signal line S1 and the third scan signal line S3 are low-level signals, and signals of the second scan signal line S2, the fourth scan signal line S4, the first light emitting signal line EM1 and the second light emitting signal line EM2 are high-level signals, so that the second transistor T2 and the fourth transistor T4 are turned on and the other switching transistors are turned off.

The second transistor T2 is turned on, so that the first node N1 and the third node N3 are turned on. Since the third transistor T3 is continuously turned on in this stage, the fourth transistor T4 is turned on so that a data signal output from the data signal line DATA is supplied to the first node N1 through the second node N2, the turned-on third transistor N3, the third node N3, and the turned-on second transistor T2, and a difference between the data voltage output from the data signal line DATA and a threshold voltage of the third transistor T3 is charged into the storage capacitor C. A voltage of the first node N1 is Vd1−|Vth|, wherein Vd is the data voltage output from the data signal line DATA, and Vth is the threshold voltage of the third transistor T3.

The third stage A3 may be referred to as a third node N3 reset stage. Signals of the second scan signal line S2 and the third scan signal line S3 are low-level signals, and signals of the first scan signal line S1, the fourth scan signal line S4, the first light emitting signal line EM1, and the second light emitting signal line EM2 are high-level signals, so that the second transistor T2 and the seventh transistor T7 are turned on and the other switching transistors are turned off.

The second transistor T2 is turned on, so that the first node N1 and the third node N3 are turned on, and a data voltage held in a parasitic capacitor at the second node N2 is continuously supplied to the first node N1 through the turned-on third transistor T3, the third node N3, and the turned-on second transistor T2, thereby prolonging compensation time of the threshold voltage of the third transistor T3, and improving uneven display of a picture caused by insufficient compensation. The seventh transistor T7 is turned on, so that a signal of the second initial signal line INIT2 is supplied to the fourth node N4 to initialize (reset) the first electrode of the light emitting device EL, and clear original charges in the first electrode of the light emitting device EL.

The fourth stage A4 may be referred to as a buffer stage. All of signals of the first scan signal line S1, the second scan signal line S2, the third scan signal line S3, the fourth scan signal line S4, the first light emitting signal line EM1, and the second light emitting signal line EM2 are high-level signals, and all switching transistors are turned off.

The fifth stage A5 may be referred to as a reset stage for the second node N2 and the third node N3. A signal of the first light emitting signal line EM1 is a low-level signal, and all signals of the first scan signal line S1, the second scan signal line S2, the third scan signal line S3, the fourth scan signal line S4, and the second light emitting signal line EM2 are high-level signals, so that the fifth transistor T5 is turned on, and the other switching transistors are turned off.

The fifth transistor T5 is turned on, so that a power supply signal output from the first power supply line VDD is supplied to the third node N3 through the turned-on fifth transistor T5, the second node N2, and the turned-on third transistor T3, and the second node N2 and the third node N3 are reset.

The sixth stage A6 may be called a light emitting stage. Signals of the first light emitting signal line EM1 and the second light emitting signal line EM2 are low-level signals, and signals of the first scan signal line S1, the second scan signal line S2, the third scan signal line S3, and the fourth scan signal line S4 are high-level signals, so that the fifth transistors T5 and the sixth transistors T6 are turned on, and the other switching transistors are turned off.

The fifth transistor T5 and the sixth transistor T6 are turned on, so that a power supply signal outputted from the first power supply line VDD provides a drive voltage to the first electrode of the light emitting device EL through the turned-on fifth transistor T5, the turned-on third transistor T3, and the turned-on sixth transistor T6 to drive the light emitting device EL to emit light. Since the fifth transistor T5 is turned on ahead of time in the fifth stage A5, the power supply signal is written to the third node N3. After the sixth transistor T6 is turned on, charges in the third node N3 is quickly transferred to the fourth node N4, so that the light emitting device EL may be turned on at a faster lighting speed, which is especially important for a lighting speed of low grayscale.

In a drive process of the pixel drive circuit, a drive current flowing through the third transistor T3 (a drive transistor) of each pixel drive circuit is determined by a voltage difference between a gate electrode and a first electrode of the third transistor T3. Since the voltage of the first node N1 is Vd−|Vth|, the drive current of the third transistor T3 is as follows.

$$I = K * {( Vgs - Vth )}^{2} = K * {[ ( Vdd - Vd + \vert Vth \vert ) - Vth ]}^{2} = K * {[ ( Vdd - Vd ]}^{2}$$

Herein, I is a drive current flowing through the third transistor T3 (that is, a drive current for driving the light emitting device EL), K is a constant related to a process and a design, Vgs is a voltage difference between the gate electrode and the first electrode of the third transistor T3, and Vdd is a voltage of a power supply signal output from the first power supply line.

It may be seen from a derivation result of the above current formula that in the light emitting stage, the drive current of the third transistor T3 of each pixel drive circuit is not affected by the threshold voltage of the third transistor T3. Therefore, an influence of the threshold voltage of the third transistor T3 on the drive current is eliminated, which may ensure uniformity of display brightness of a display product, and improve an overall display effect of the display product.

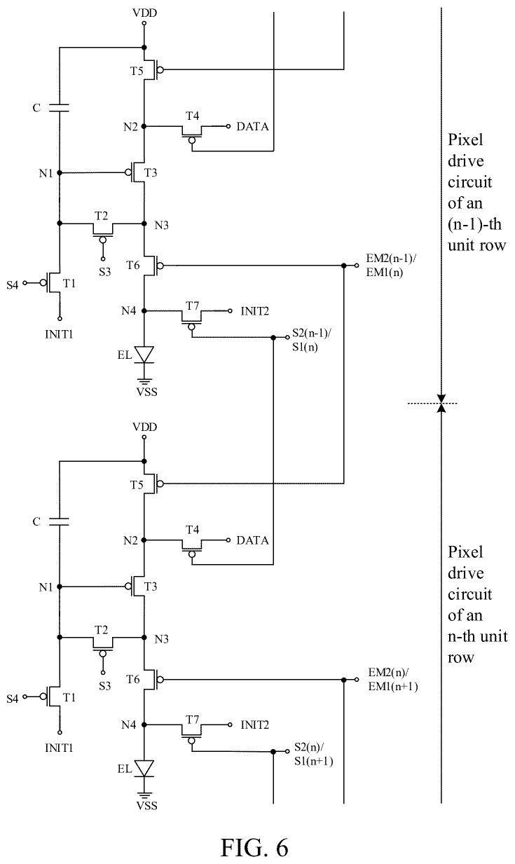

FIG. 6 is an equivalent circuit diagram of cascaded pixel drive circuits in an exemplary embodiment of the present disclosure, schematically illustrating pixel drive circuits of an (n−1)-th unit row and an n-th unit row, wherein structures of the pixel drive circuits of the (n−1)-th unit row and the n-th unit row are substantially the same as those shown in FIG. 4, and n is a positive integer greater than 1.

As shown in FIG. 6, a second light emitting signal line EM2 (n−1) of the (n−1)-th unit row may simultaneously act as a first light emitting signal line EM1 (n) of the n-th unit row. That is, the second light emitting signal line EM2 (n−1) of the (n−1)-th unit row and the first light emitting signal line EM1 (n) of the n-th unit row are a same light emitting signal line, and a sixth transistor T6 of the (n−1)-th unit row and a fifth transistor T5 of the n-th unit row share the same light emitting signal line. A second scan signal line S2(n−1) of the (n−1)-th unit row may simultaneously act as a first scan signal line S1(n) of the n-th unit row. That is, the second scan signal line S2(n−1) of the (n−1)-th unit row and the first scan signal line S1(n) of the n-th unit row are a same scan signal line, and a seventh transistor T7 of the (n−1)-th unit row and a fourth transistor T4 of the n-th unit row share the same scan signal line.

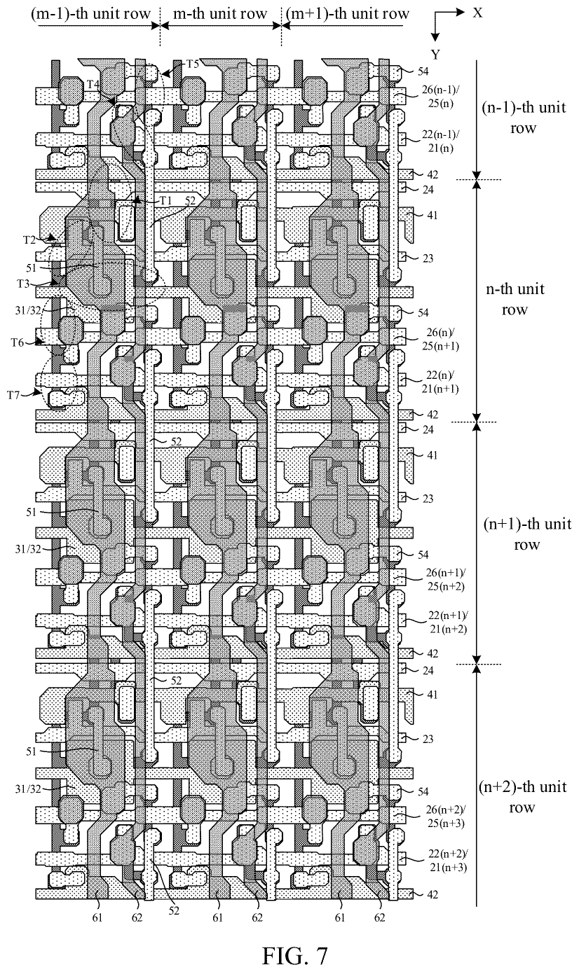

FIG. 7 is a schematic diagram of a planar structure of a display substrate in an exemplary embodiment of the present disclosure, illustrating a structure of nine circuit units (three unit rows and three unit columns). In an exemplary implementation mode, the display substrate may include a plurality of circuit units, the plurality of circuit units may form a plurality of unit rows and a plurality of unit columns, a plurality of circuit units in each unit row are sequentially arranged along a first direction X, and a plurality of unit rows are sequentially arranged along a second direction Y, constituting a circuit unit array arranged in an array, and the first direction X intersects with the second direction Y.

As shown in FIG. 7, at least one circuit unit may include a pixel drive circuit, and a scan signal line connected with the pixel drive circuit, a third scan signal line 23, a fourth scan signal line 24, a light emitting signal line, a first initial signal line 41, a second initial signal line 42, a first power supply line 61, and a data signal line 62. In an exemplary implementation mode, the scan signal line, the third scan signal line 23, the fourth scan signal line 24, the light emitting signal line, the first initial signal line 41, and the second initial signal line 42 may be in a shape of a straight line or a polyline in which a main portion extends along the first direction X, and the first power supply line 61 and the data signal line 62 may be in a shape of a straight line or a polyline in which a main portion extends along the second direction Y.

In the present disclosure, “A extends along a B direction” refers to that A may include a main portion and a secondary portion connected with the main portion, wherein the main portion is a line, a line segment, or a strip-shaped body, the main portion extends along the B direction, and a length of the main portion extending along the B direction is greater than a length of the secondary portion extending along another direction. In following description, “A extends along a B direction” means “a main portion of A extends along a B direction”.

In an exemplary implementation mode, at least one pixel drive circuit may include at least a storage capacitor and a plurality of transistors, the storage capacitor may include a first electrode plate and a second electrode plate which are stacked, the plurality of transistors may include a first transistor T1 as a first initialization transistor, a second transistor T2 as a compensation transistor, a third transistor T3 as a drive transistor, a fourth transistor T4 as a data writing transistor, a fifth transistor T5 as a first light emitting control transistor, a sixth transistor T6 as a second light emitting control transistor, and a seventh transistor T7 as a second initialization transistor. The first transistor T1 to the seventh transistor T7 may be low temperature poly silicon transistors.

In an exemplary implementation mode, a gate electrode of the first transistor T1 is connected with the fourth scan signal line 24, a first electrode of the first transistor T1 is connected with the first initial signal line 41, a second electrode of the first transistor T1 and a first electrode of the second transistor T2 are connected with a gate electrode of the third transistor T3 (the first electrode plate of the storage capacitor), a gate electrode of the second transistor T2 is connected with the third scan signal line 23, a second electrode of the second transistor T2, a second electrode of the third transistor T3, and a first electrode of the sixth transistor T6 are connected with each other, a first electrode of the third transistor T3, a second electrode of the fourth transistor T4, and a second electrode of the fifth transistor T5 are connected with each other, a first electrode of the fourth transistor T4 is connected with the data signal line 62, a first electrode of the fifth transistor T5 is connected with the first power supply line 61, a second electrode of the sixth transistor T6 is connected with a second electrode of the seventh transistor T7, and a first electrode of the seventh transistor T7 is connected with the second initial signal line 42.

In an exemplary implementation mode, a light emitting signal line of at least one unit row, on one hand, may act as a second light emitting signal line 26 of a pixel drive circuit in the present unit row, and on the other hand, may act as a first light emitting signal line 25 of a pixel drive circuit in a next unit row. That is, a first light emitting signal line 25 of a pixel drive circuit in the present unit row and a second light emitting signal line 26 of a pixel drive circuit in a previous unit row are a same light emitting signal line, or the second light emitting signal line 26 of the pixel drive circuit in the present unit row and a first light emitting signal line 25 of a pixel drive circuit in a next unit row are a same light emitting signal line. For example, a light emitting signal line in an (n−1)-th unit row, on one hand, acts as a second light emitting signal line 26(n−1) of a pixel drive circuit in the (n−1)-th unit row, and on the other hand, acts as a first light emitting signal line 25(n) of a pixel drive circuit in an n-th unit row. For another example, a light emitting signal line in the n-th unit row, on one hand, acts as a second light emitting signal line 26(n) of the pixel drive circuit in the n-th unit row, and on the other hand, acts as a first light emitting signal line 25(n+1) of a pixel drive circuit in an (n+1)-th unit row. For yet another example, a light emitting signal line in the (n+1)-th unit row, on one hand, acts as a second light emitting signal line 26(n+1) of the pixel drive circuit in the (n+1)-th unit row, and one the other hand, acts as a first light emitting signal line 25(n+2) of a pixel drive circuit in an (n+2)-th unit row.

In an exemplary implementation mode, in at least one pixel drive circuit in at least one unit row, a gate electrode of a fifth transistor T5 is connected with a light emitting signal line in a previous unit row, a gate electrode of a sixth transistor T6 is connected with a light emitting signal line in a current unit row, the gate electrode of the fifth transistor T5 of the pixel drive circuit in the current unit row and a gate electrode of a sixth transistor T6 of a pixel drive circuit in a previous unit row are connected with a same light emitting signal line, or the gate electrode of the sixth transistor T6 of the pixel drive circuit in the current unit row and a gate electrode of a fifth transistor T5 of a pixel drive circuit in a next unit row are connected with a same light emitting signal line. For example, a gate electrode of a sixth transistor T6 of a pixel drive circuit in an (n−1)-th unit row and a gate electrode of a fifth transistor T5 of a pixel drive circuit in an n-th unit row are simultaneously connected with a light emitting signal line in the (n−1)-th unit row. The light emitting signal line acts as both a second light emitting signal line 26(n−1) of the pixel drive circuit in the (n−1)-th unit row and a first light emitting signal line 25(n) of a pixel drive circuit in an n-th unit row. For another example, a gate electrode of a sixth transistor T6 of the pixel drive circuit in the n-th unit row and a gate electrode of a fifth transistor T5 of a pixel drive circuit in an (n+1)-th unit row are simultaneously connected with a light emitting signal line in the n-th unit row. The light emitting signal line acts as both a second light emitting signal line 26(n) of the pixel drive circuit in the n-th unit row and a first light emitting signal line 25(n+1) of the pixel drive circuit in the (n+1)-th unit row. For yet another example, a gate electrode of a sixth transistor T6 of a pixel drive circuit in an (n+1)-th unit row and a gate electrode of a fifth transistor T5 of a pixel drive circuit in an (n+2)-th unit row are simultaneously connected with a light emitting signal line in the (n+1)-th unit row. The light emitting signal line acts as both a second light emitting signal line 26(n+1) of the pixel drive circuit in the (n+1)-th unit row and a first light emitting signal line 25(n+2) of the pixel drive circuit in the (n+2)-th unit row.

In an exemplary implementation mode, a scan signal line of at least one unit row, on one hand, may act as a second scan signal line 22 of a pixel drive circuit in a current unit row, and on the other hand, may act as a first scan signal line 21 of a pixel drive circuit in a next unit row. That is, a first scan signal line 21 of the pixel drive circuit in the current unit row and a second scan signal line 22 of a pixel drive circuit in a previous unit row are a same scan signal line, or the second scan signal line 22 of the pixel drive circuit in the current unit row and the first scan signal line 21 of the pixel drive circuit in the next unit row are a same scan signal line. For example, a scan signal line of an (n−1)-th unit row, on one hand, acts as a second scan signal line 22(n−1) of a pixel drive circuit in the (n−1)-th unit row, and on the other hand, acts as a first scan signal line 21(n) of a pixel drive circuit in an n-th unit row. For another example, a scan signal line in an n-th unit row, on one hand, acts as a second scan signal line 22(n) of a pixel drive circuit in the n-th unit row, and on the other hand, acts as a first scan signal line 21(n+1) of a pixel drive circuit in an (n+1)-th unit row. For yet another example, a scan signal line in an (n+1)-th unit row, on one hand, acts as a second scan signal line 22(n+1) of a pixel drive circuit in the (n+1)-th unit row, and on the other hand, acts as a first scan signal line 21(n+2) of a pixel drive circuit in an (n+2)-th unit row.

In an exemplary implementation mode, in at least one pixel drive circuit in at least one unit row, a gate electrode of a fourth transistor T4 is connected with a scan signal line in a previous unit row, a gate electrode of a seventh transistor T7 is connected with a scan signal line in a current unit row. The gate electrode of the fourth transistor T4 of the pixel drive circuit in the current unit row and a gate electrode of a seventh transistor T7 of a pixel drive circuit in the previous unit row are connected with a same scan signal line, or the gate electrode of the seventh transistor T7 of the pixel drive circuit in the current unit row and a gate electrode of a fourth transistor T4 of a pixel drive circuit in a next unit row are connected with a same scan signal line. For example, a gate electrode of a seventh transistor T7 of a pixel drive circuit in an (n−1)-th unit row and a gate electrode of a fourth transistor T4 of a pixel drive circuit in an n-th unit row are simultaneously connected with a scan signal line in the (n−1)-th unit row. The scan signal line acts as a second scan signal line 22(n−1) of the pixel drive circuit in the (n−1)-th unit row, and also acts as a first scan signal line 21(n) of the pixel drive circuit in the n-th unit row. For another example, a gate electrode of a seventh transistor T7 of a pixel drive circuit in an n-th unit row and a gate electrode of a fourth transistor T4 of a pixel drive circuit in an (n+1)-th unit row are simultaneously connected with a scan signal line in the n-th unit row. The scan signal line acts as a second scan signal line 22(n) of the pixel drive circuit in the n-th unit row, and also acts as a first scan signal line 21(n+1) of the pixel drive circuit in the (n+1)-th unit row. For yet another example, a gate electrode of a seventh transistor T7 of a pixel drive circuit in an (n+1)-th unit row and a gate electrode of a fourth transistor T4 of a pixel drive circuit in an (n+2)-th unit row are simultaneously connected with a scan signal line in the (n+1)-th unit row. The scan signal line acts as a second scan signal line 22(n+1) of the pixel drive circuit in the (n+1)-th unit row, and also acts as a first scan signal line 21(n+2) of the pixel drive circuit in the (n+2)-th unit row.

In an exemplary implementation mode, in at least one pixel drive circuit, a fifth transistor T5 and a sixth transistor T6 may be disposed on both sides of a third transistor T3 in the second direction Y (unit column direction), respectively. For example, in a pixel drive circuit in an n-th unit row, a fifth transistor T5 may be disposed on a side of the third transistor T3 in an opposite direction of the second direction Y, and the sixth transistor T6 may be disposed on a side of the third transistor T3 in the second direction Y.

In an exemplary implementation mode, in at least one pixel drive circuit, a fourth transistor T4 and a seventh transistor T7 may be disposed on both sides of a third transistor T3 in the second direction Y (unit column direction), respectively. For example, in a pixel drive circuit in an n-th unit row, a fourth transistor T4 may be disposed on a side of the third transistor T3 in an opposite direction of the second direction Y, and the seventh transistor T7 may be disposed on a side of the third transistor T3 in the second direction Y.

In an exemplary implementation mode, the fifth transistor T5 may include, at least, a fifth active layer, and the sixth transistor T6 may include, at least, a sixth active layer. In at least one pixel drive circuit in at least one unit row, the fifth active layer may be disposed in a circuit unit in a previous unit row, and a sixth active layer may be disposed in a circuit unit in a current unit row. For example, in a pixel drive circuit in an n-th unit row, the fifth active layer may be disposed in a circuit unit in an (n−1)-th unit row, and the sixth active layer may be disposed in a circuit unit in an n-th unit row.

In an exemplary implementation mode, the fourth transistor T4 may include, at least, a fourth active layer, and the seventh transistor T7 may include, at least, a seventh active layer. In at least one pixel drive circuit in at least one unit row, a fourth active layer may be disposed in a circuit unit in a previous unit row, and a seventh active layer may be disposed in a circuit unit in a current unit row. For example, in a pixel drive circuit in an n-th unit row, a fourth active layer may be disposed in a circuit unit in an (n−1)-th unit row, and a seventh active layer may be disposed in a circuit unit in an n-th unit row.

In an exemplary implementation mode, in at least one pixel drive circuit in at least one unit row, a fifth active layer may be disposed on a side of a sixth active layer of a pixel drive circuit in a previous unit row in the first direction X (unit row direction). For example, in a pixel drive circuit in an n-th unit row, a fifth active layer may be disposed on a side of a sixth active layer of a pixel drive circuit in an (n−1)-th unit row in the first direction X.

In an exemplary implementation mode, in at least one pixel drive circuit in at least one unit row, a fourth active layer may be disposed on a side of a seventh active layer of a pixel drive circuit in a previous unit row in the first direction X (unit row direction). For example, in a pixel drive circuit in an n-th unit row, a fourth active layer may be disposed on a side of a seventh active layer of a pixel drive circuit in an (n−1)-th unit row in the first direction X.

In an exemplary implementation mode, the pixel drive circuit may further include a storage capacitor and a fourth connection electrode 54, wherein the fourth connection electrode 54 may act as a power supply connection electrode in the present disclosure. The storage capacitor may include a first electrode plate 31 and a second electrode plate 32, an orthographic projection of the first electrode plate 31 on a plane of the display substrate is overlapped, at least partially, with an orthographic projection of the second electrode plate 32 on the plane of the display substrate. In at least one pixel drive circuit in at least one unit row, a first end of the fourth connection electrode 54 is connected with a first region of a fifth active layer of a pixel drive circuit in a next unit row, and a second end of the fourth connection electrode 54 is connected with a second electrode plate 32 of a pixel drive circuit in a current unit row. For example, in a pixel drive circuit of an n-th unit row, a first end of a fourth connection electrode 54 is connected with a first region of a fifth active layer of a pixel drive circuit in an (n+1)-th unit row, and a second end of the fourth connection electrode 54 is connected with a second electrode plate 32 of the pixel drive circuit in the n-th unit row. For another example, in a pixel drive circuit of an (n+1)-th unit row, a first end of a fourth connection electrode 54 is connected with a first region of a fifth active layer of a pixel drive circuit in an (n+2)-th unit row, and a second end of the fourth connection electrode 54 is connected with a second electrode plate 32 of the pixel drive circuit in the (n+1)-th unit row.

In an exemplary implementation mode, the second electrode of the first transistor T1 and the first electrode of the second transistor T2 may be connected with the first electrode plate 31 (the gate electrode of the third transistor T3) through a first connection electrode 51, wherein the first connection electrode 51 may act as a first node electrode in the present disclosure.

In an exemplary implementation mode, an orthographic projection of the first power supply line 61 on the plane of the display substrate is overlapped, at least partially, with an orthographic projection of the first connection electrode 51 on the plane of the display substrate.

In an exemplary implementation mode, the first electrode of the third transistor T3, the second electrode of the fourth transistor T4, and the second electrode of the fifth transistor T5 may be connected with each other through a second connection electrode 52, wherein the second connection electrode 52 may act as a second node electrode in the present disclosure.

In an exemplary implementation mode, an orthographic projection of the second connection electrode 52 on the plane of the display substrate is overlapped, at least partially, with an orthographic projection of a first initial signal line 41 on the plane of the display substrate, and/or, an orthographic projection of the second connection electrode 52 on the plane of the display substrate is overlapped, at least partially, with an orthographic projection of a second initial signal line 42 on the plane of the display substrate.

In an exemplary implementation mode, an orthographic projection of the second connection electrode 52 on the plane of the display substrate is overlapped, at least partially, with an orthographic projection of a third scan signal line 23 on the plane of the display substrate.

In an exemplary implementation mode, an orthographic projection of the second connection electrode 52 on the plane of the display substrate is overlapped, at least partially, with an orthographic projection of a fourth scan signal line 24 on the plane of the display substrate.

In an exemplary implementation mode, the first initial signal line 41 is connected with a first shield electrode, an orthographic projection of the first shield electrode on the plane of the display substrate is overlapped, at least partially, with an orthographic projection of a node between two gate electrodes in the second transistor T2 on the plane of the display substrate.

In an exemplary implementation mode, the second initial signal line 42 is connected with a second shield electrode, an orthographic projection of the second shield electrode on the plane of the display substrate is overlapped, at least partially, with an orthographic projection of a node between two gate electrodes in the first transistor T1 on the plane of the display substrate.

In an exemplary implementation mode, in a direction perpendicular to the display substrate, the display substrate may include a semiconductor layer disposed on the base substrate, a first conductive layer disposed on a side of the semiconductor layer away from the base substrate, a second conductive layer disposed on a side of the first conductive layer away from the base substrate, a third conductive layer disposed on a side of the second conductive layer away from the base substrate, and a fourth conductive layer disposed on a side of the third conductive layer away from the base substrate. The semiconductor layer may include, at least, active layers of the first transistor T1 to the seventh transistor T7. The first conductive layer may include, at least, a scan signal line, the third scan signal line 23, the fourth scan signal line 24, a light emitting signal line, and the first electrode plate 31 of the storage capacitor. The second conductive layer may include, at least, the first initial signal line 41, the second initial signal line 42, and the second electrode plate 32 of the storage capacitor. The third conductive layer may include, at least, a plurality of connection electrodes. The fourth conductive layer may include, at least, the first power supply line 61 and the data signal line 62.

Exemplary description is made below through a preparation process of a display substrate. A “patterning process” mentioned in the present disclosure includes a treatment such as deposition of a film layer, photoresist coating on a film layer, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in an entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary implementation mode of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

In an exemplary implementation mode, nine circuit units (three unit rows and three unit columns) are taken as an example, the preparation process of the display substrate in the embodiment may include following acts.

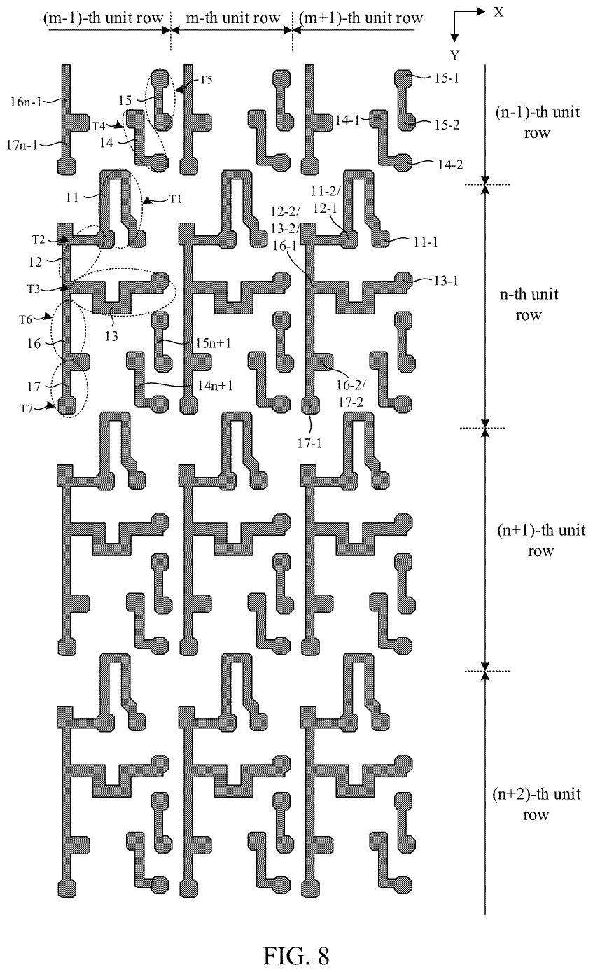

(1) A pattern of a semiconductor layer is formed. In an exemplary implementation mode, forming the pattern of the semiconductor layer may include: a first insulation thin film and a semiconductor thin film are deposited sequentially on a base substrate, and the semiconductor thin film is patterned through a patterning process to form a first insulation layer disposed on the base substrate and the pattern of the semiconductor layer disposed on the first insulation layer, as shown in FIG. 8.

In an exemplary implementation mode, a pattern of a semiconductor layer in each circuit unit may include, at least, a first active layer 11 of a first transistor T1 to a seventh active layer 17 of a seventh transistor T7, wherein the first active layer 11, the second active layer 12, the third active layer 13, the sixth active layer 16, and the seventh active layer 17 may be connected with each other to form an integral structure, and the fourth active layer 14 and the fifth active layer 15 are disposed separately.

In an exemplary implementation mode, in a pixel drive circuit of a current circuit unit, in a first direction X, the fourth active layer 14 and the fifth active layer 15 may be located on a side of the third active layer 13 in the current circuit unit in the first direction X, and the sixth active layer 16 and the seventh active layer 17 may be located on a side of the third active layer 13 in the current circuit unit in an opposite direction of the first direction X. In a second direction Y, the sixth active layer 16 and the seventh active layer 17 may be located on a side of the third active layer 13 in the current circuit unit in the second direction Y, and the first active layer 11, the second active layer 12, the fourth active layer 14, and the fifth active layer 15 may be located on a side of the third active layer 13 in the current circuit unit in an opposite direction of the second direction Y.

In an exemplary implementation mode, the third active layer 13 may be in a shape of an inverted “Ω” letter, the first active layer 11 may be in a shape of an inverted “n” letter, the second active layer 12 and the fourth active layer 14 may be in a shape of an “L” letter, and the fifth active layer 15, the sixth active layer 16, and the seventh active layer 17 may be in a shape of an inverted “I” letter.

In an exemplary implementation mode, each of the first active layer 11 to the seventh active layer 17 may include a first region, a second region, and a channel region located between the first region and the second region.

In an exemplary implementation mode, a second region 11-2 of the first active layer and a first region 12-1 of the second active layer may be connected with each other, so that the second region 11-2 of the first active layer may act as the first region 12-1 of the second active layer. A second region 12-2 of the second active layer, a second region 13-2 of the third active layer, and a first region 16-1 of the sixth active layer may be connected with each other, and the second region 12-2 of the second active layer may simultaneously act as the second region 13-2 of the third active layer and the first region 16-1 of the sixth active layer. A second region 16-2 of the sixth active layer and a second region 17-2 of the seventh active layer may be connected with each other, and the second region 16-2 of the sixth active layer may act as the second region 17-2 of the seventh active layer. A first region 11-1 of the first active layer, a first region 13-1 of the third active layer, a first region 14-1 of the fourth active layer, a second region 14-2 of the fourth active layer, a first region 15-1 of the fifth active layer, a second region 15-2 of the fifth active layer, and a first region 17-1 of the seventh active layer may be disposed separately.

In an exemplary implementation mode, in one unit column, a fourth active layer 14 and a fifth active layer 15 of a pixel drive circuit in a current circuit unit may be disposed in a circuit unit of a previous unit row, and a first active layer 11, a second active layer 12, a third active layer 13, a sixth active layer 16, and a seventh active layer 17 may be disposed in a current circuit unit.

In an exemplary implementation mode, a fifth active layer 15 of a pixel drive circuit in a circuit unit in a current unit row may be located on a side of a sixth active layer 16 of a pixel drive circuit in a circuit unit in a previous unit row in the first direction X, so that a fifth active layer 15 and a sixth active layer 16 in two unit rows may share a light emitting signal line, and the light emitting signal line may simultaneously control turn-on and turn-off of the sixth transistor T6 in the current unit row and a fifth transistor T5 in a next unit row. For example, a fifth active layer 15 of a pixel drive circuit in an n-th unit row is disposed in a circuit unit in an (n−1)-th unit row, so that the fifth active layer 15 of the pixel drive circuit in the n-th unit row and a sixth active layer 16n-1 of a pixel drive circuit in the (n−1)-th unit row may share a light emitting signal line, and the light emitting signal line may simultaneously control turn-on and turn-off of the fifth transistor T5 in the n-th unit row and the sixth transistor T6 in the (n−1)-th unit row. For another example, a fifth active layer 15n+1 of a pixel drive circuit in an (n+1)-th unit row is disposed in a circuit unit in the n-th unit row, so that the fifth active layer 15n+1 of the pixel drive circuit in the (n+1)-th unit row and a sixth active layer 16 of the pixel drive circuit in the n-th unit row may share a light emitting signal line, and the light emitting signal line may simultaneously control turn-on and turn-off of the fifth transistor T5 in the (n+1)-th unit row and the sixth transistor T6 in the n-th unit row.

In an exemplary implementation mode, a fourth active layer 14 of a pixel drive circuit in a circuit unit in a current unit row may be located on a side of a seventh active layer 17 of a pixel drive circuit in a circuit unit in a previous unit row in the first direction X, so that a fourth active layer 14 and a seventh active layer 17 in two unit rows may share a scan signal line, and the scan signal line may simultaneously control turn-on and turn-off of a seventh transistor T7 in the current unit row and a fourth transistor T4 in a next unit row. For example, a fourth active layer 14 of a pixel drive circuit in an n-th unit row is disposed in a circuit unit of an (n−1)-th unit row, so that a fourth active layer 14 of the pixel drive circuit in the n-th unit row and a seventh active layer 17n−1 of a pixel drive circuit in the (n−1)-th unit row may share a scan signal line, and the scan signal line may simultaneously control turn-on and turn-off of a seventh transistor T7 in the (n−1)-th unit row and a fourth transistor T4 in the n-th unit row. For another example, a fourth active layer 14n+1 of a pixel drive circuit in an (n+1)-th unit row is disposed in a circuit unit in the n-th unit row, so that the fourth active layer 14n+1 of the pixel drive circuit in the (n+1)-th unit row and a seventh transistor T7 of the pixel drive circuit in the n-th unit row may share a scan signal line, and the scan signal line may simultaneously control turn-on and turn-off of the seventh transistor T7 in the n-th unit row and a fourth transistor T4 in the (n+1)-th unit row.

In an exemplary implementation mode, the semiconductor layer may be made of poly silicon (p-Si). That is, the first transistor T1 to the seventh transistor T7 are LTPS transistors. In an exemplary implementation mode, patterning the semiconductor thin film through a patterning process may include: an amorphous silicon (a-si) thin film is formed on the first insulation thin film, the amorphous silicon thin film is dehydrogenated, and the dehydrogenated amorphous silicon thin film is crystallized to form a poly silicon thin film. Subsequently, the poly silicon thin film is patterned to form the pattern of the semiconductor layer.

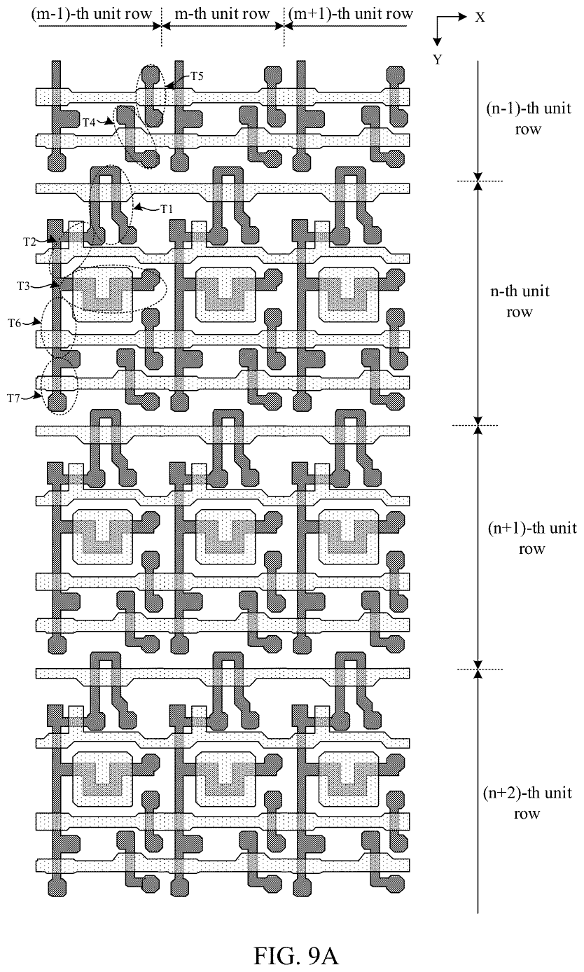

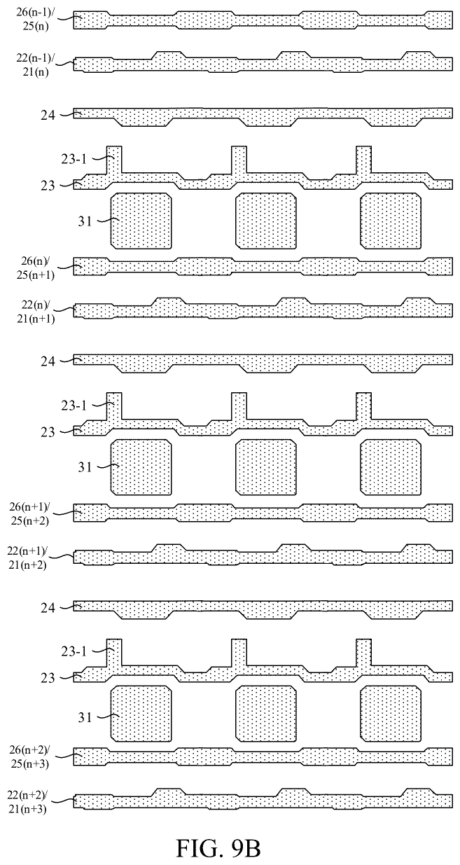

(2) A pattern of a first conductive layer is formed. In an exemplary implementation mode, forming the pattern of the first conductive layer may include: a second insulation thin film and a first conductive thin film are deposited sequentially on the base substrate on which the aforementioned patterns are formed, and the first conductive thin film is patterned through a patterning process to form a second insulation layer that covers the pattern of the semiconductor layer and form the pattern of the first conductive layer disposed on the second insulation layer, as shown in FIG. 9A and FIG. 9B, wherein FIG. 9B is a schematic plan view of the first conductive layer in FIG. 9A. In an exemplary implementation mode, the first conductive layer may be referred to as a first gate metal (GATE1) layer.

In an exemplary implementation mode, a pattern of a first conductive layer of each circuit unit may include, at least, a scan signal line, a third scan signal line 23, a fourth scan signal line 24, a light emitting signal line, and a first electrode plate 31 of a storage capacitor.

In an exemplary implementation mode, the first electrode plate 31 may be in a shape of a rectangle, and a chamfer or a groove may be provided at a corner of the rectangle. An orthographic projection of the first electrode plate 31 on the base substrate is overlapped, at least partially, with an orthographic projection of the third active layer of the third transistor T3 on the base substrate. In an exemplary implementation mode, the first electrode plate 31 may act as one electrode plate of the storage capacitor and a gate electrode of the third transistor T3 simultaneously.

In an exemplary implementation mode, the scan signal line may be in a shape of a straight line or a polyline in which a main portion extends along the first direction X, the scan signal line may be located on a side of the first electrode plate 31 in the second direction Y, a region where the scan signal line is overlapped with the fourth active layer may act as a gate electrode of the fourth transistor T4, and a region where the scan signal line is overlapped with the seventh active layer may act as a gate electrode of the seventh transistor T7.

In an exemplary implementation mode, the scan signal line may act as a second scan signal line 22 of a pixel drive circuit in a current unit row, and also act as a first scan signal line 21 of a pixel drive circuit in a next unit row. For example, a scan signal line in an (n−1)-th unit row may act as a second scan signal line 22(n−1) of a pixel drive circuit in the (n−1)-th unit row, and may simultaneously act as a first scan signal line 21(n) of a pixel drive circuit in an n-th unit row. For another example, a scan signal line in an n-th unit row may act as a second scan signal line 22(n) of a pixel drive circuit in the n-th unit row, and may simultaneously act as a first scan signal line 21(n+1) of a pixel drive circuit in an (n+1)-th unit row. For another example, a scan signal line in an (n+1)-th unit row may act as a second scan signal line 22(n+1) of a pixel drive circuit in the (n+1)-th unit row, and may simultaneously act as a first scan signal line 21(n+2) of a pixel drive circuit in an (n+2)-th unit row.

In an exemplary implementation mode, the third scan signal line 23 may be in a shape of a straight line or a polyline in which a main portion extends along the first direction X, and the third scan signal line 23 may be located on a side of the first electrode plate 31 in an opposite direction of the second direction Y. A third gate block 23-1 is provided on the third scan signal line 23, the third gate block 23-1 may be in a shape of a strip extending along the second direction Y, a first end of the third gate block 23-1 is connected with a side of the third scan signal line 23 away from the first electrode plate 31, and a second end of the third gate block 23-1 extends in a direction away from the first electrode plate 31. A region where the third scan signal line 23 and the third gate block 23-1 are overlapped with the second active layer may act as a gate electrode of the second transistor T2 with a dual-gate structure.

In an exemplary implementation mode, the fourth scan signal line 24 may be in a shape of a straight line or a polyline in which a main portion extends along the first direction X, the fourth scan signal line 24 may be located on a side of the third scan signal line 23 away from the first electrode plate 31, and a region where the fourth scan signal line 24 is overlapped with the first active layer may act as a gate electrode of the first transistor T1 with a dual-gate structure.

In an exemplary implementation mode, the light emitting signal line may be in a shape of a straight line or a polyline in which a main portion extends along the first direction X, the light emitting signal line may be located on a side of the first electrode plate 31 in the second direction Y, a region where the light emitting signal line is overlapped with the fifth active layer may act as a gate electrode of the fifth transistor T5, and a region where the light emitting signal line is overlapped with the sixth active layer may act as a gate electrode of the sixth transistor T6.

In an exemplary implementation mode, the light emitting signal line may act as a second light emitting signal line 26 of a pixel drive circuit in a current unit row, and also act as a first light emitting signal line 25 of a pixel drive circuit in a next unit row. For example, a light emitting signal line in an (n−1)-th unit row may act as a second light emitting signal line 26(n−1) of a pixel drive circuit in the (n−1)-th unit row, and may simultaneously act as a first light emitting signal line 25(n) of a pixel drive circuit in an n-th unit row. For another example, a light emitting signal line in an n-th unit row may act as a second light emitting signal line 26(n) of a pixel drive circuit in the n-th unit row, and may simultaneously act as a first light emitting signal line 25(n+1) of a pixel drive circuit in an (n+1)-th unit row. For yet another example, a light emitting signal line in an (n+1)-th unit row may act as a second light emitting signal line 26(n+1) of a pixel drive circuit in the (n+1)-th unit row, and may simultaneously act as a first light emitting signal line 25(n+2) of a pixel drive circuit in an (n+2)-th unit row.

In an exemplary implementation mode, the scan signal line, the third scan signal line 23, the fourth scan signal line 24, and the light emitting signal line may be designed with unequal widths, and the widths are dimensions in the second direction Y, so that not only a layout of a pixel structure may be facilitated, but also a parasitic capacitance between signal lines may be reduced, which is not limited here in the present disclosure.

In an exemplary implementation mode, the scan signal line, the third scan signal line 23, the fourth scan signal line 24, and the light emitting signal line may include a region overlapped with the semiconductor layer and a region not overlapped with the semiconductor layer, wherein widths of signal lines in the region overlapped with the semiconductor layer may be greater than widths of signal lines in the region not overlapped with the semiconductor layer.

In an exemplary implementation mode, after the pattern of the first conductive layer is formed, the semiconductor layer may be made to be conductive by using the first conductive layer as a shield, a semiconductor layer in a region shielded by the first conductive layer forms channel regions of the first transistor T1 to the seventh transistor T7, and a semiconductor layer in a region not shielded by the first conductive layer is made to be conductive. That is, all of first regions and second regions of the first active layer 11 to the seventh active layer 17 are made to be conductive.

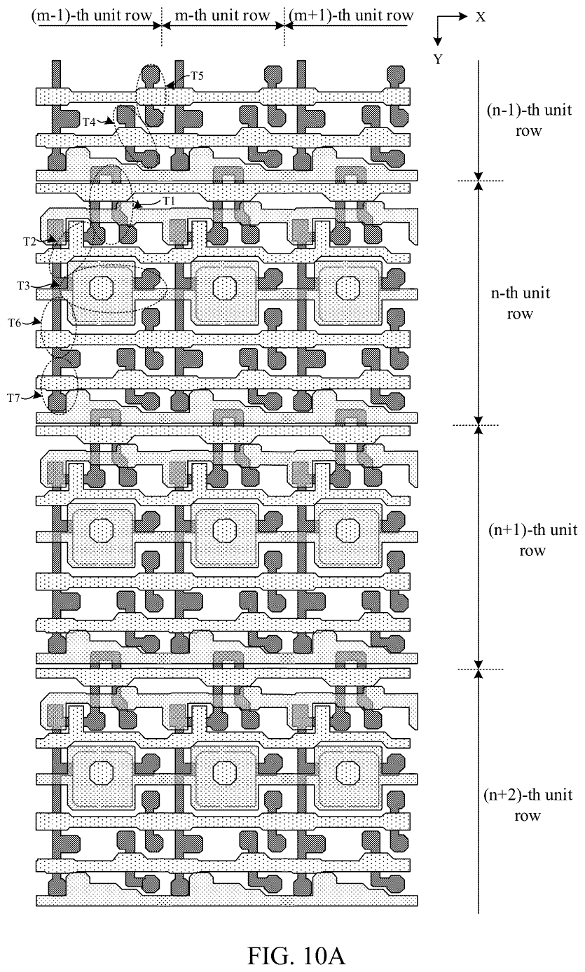

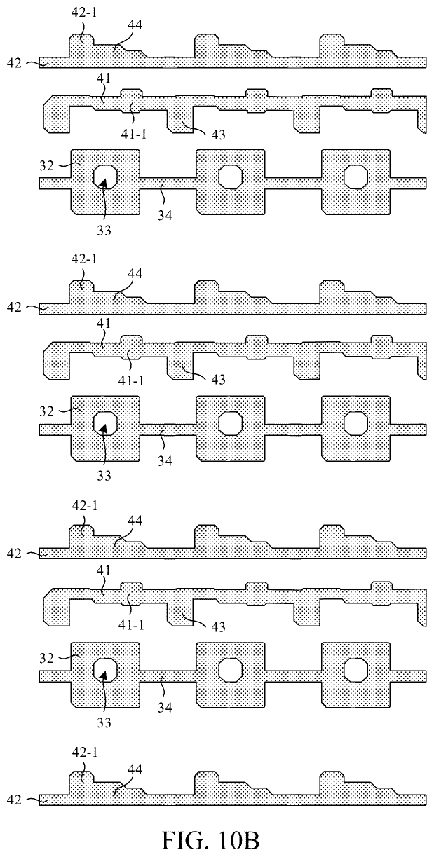

(3) A pattern of a second conductive layer is formed. In an exemplary implementation mode, forming the pattern of the second conductive layer may include: a third insulation thin film and a second conductive thin film are sequentially deposited on the base substrate on which the aforementioned patterns are formed, and the second conductive thin film is patterned through a patterning process to form a third insulation layer that covers the first conductive layer, and a pattern of a second conductive layer disposed on the third insulation layer, as shown in FIGS. 10A and 10B, wherein FIG. 10B is a schematic plan view of the second conductive layer in FIG. 10A. In an exemplary implementation mode, the second conductive layer may be referred to as a second gate metal (GATE2) layer.

In an exemplary implementation mode, a pattern of a second conductive layer of each circuit unit includes, at least, a second electrode plate 32 of the storage capacitor, a first initial signal line 41, a second initial signal line 42, a first shield electrode 43, and a second shield electrode 44.

In an exemplary implementation mode, a profile of the second electrode plate 32 may be in a shape of a rectangle, a chamfer or a groove may be provided at a corner of the rectangle. An orthographic projection of the second electrode plate 32 on the base substrate is overlapped, at least partially, with an orthographic projection of the first electrode plate 31 on the base substrate. The second electrode plate 32 may serve as another electrode plate of the storage capacitor, and the first electrode plate 31 and the second electrode plate 32 form the storage capacitor of the pixel drive circuit.

In an exemplary implementation mode, the second electrode plate 32 is provided with an opening 33. The opening 33 may have a rectangular shape and may be located in a middle region of the second electrode plate 32, so that the second electrode plate 32 forms an annular structure. The opening 33 exposes the third insulation layer covering the first electrode plate 31, and an orthographic projection of the first electrode plate 31 on the base substrate contains an orthographic projection of the opening 33 on the base substrate. In an exemplary implementation mode, the opening 33 is configured to accommodate a tenth via to be formed subsequently, and the tenth via is located within the opening 33 and exposes the first electrode plate 31, so that a first connection electrode to be formed subsequently is connected with the first electrode plate 31 through the via.

In an exemplary implementation mode, an electrode plate connection block 34 may be provided on the second electrode plate 32. The electrode plate connection block 34 may be in a shape of a strip extending along the first direction X, and the electrode plate connection block 34 may be disposed on a side of the second electrode plate 32 in the first direction X or on a side of the second electrode plate 32 in an opposite direction of the first direction X. A first end of the electrode plate connection block 34 is connected with the second electrode plate 32 in a current circuit unit, and the electrode plate connection block 34 is connected with a second electrode plate 32 in an adjacent circuit unit in the first direction X, so that second electrode plates 72 in adjacent circuit units in one unit row are connected with each other to form an integral structure. Since a second electrode plate 32 in each circuit unit is connected with a first power supply line to be formed subsequently, the second electrode plates 32 of adjacent circuit units are connected with each other to form an integral structure, the second electrode plates in the integral structure may be multiplexed into a power supply signal line, so that a plurality of second electrode plates in a unit row may be ensured to be have a same potential, which is beneficial for improving uniformity of the display substrate, avoiding poor display of the display substrate and ensuring a display effect of the display substrate.

In an exemplary implementation mode, the first initial signal line 41 may be in a shape of a straight line or a polyline in which a main portion extends along the first direction X, the first initial signal line 41 may be located between the third scan signal line 23 and the fourth scan signal line 24, and the first initial signal line 41 is configured to be connected with the first region of the first active layer through a sixth connection electrode formed subsequently.

In an exemplary implementation mode, a first initial connection block 41-1 may be provided on the first initial signal line 41. The first initial connection block 41-1 may be in a shape of a block (e.g., a rectangle), and connected with the first initial signal line 41. The first initial connection block 41-1 is configured to be connected with the first region of the first active layer through a sixth connection electrode formed subsequently.

In an exemplary implementation mode, the first shield electrode 43 may be in a shape of a block (e.g., a rectangle), may be disposed on a side of the first initial signal line 41 close to the second electrode plate 32, and may be connected with the first initial signal line 41. An orthographic projection of the first shield electrode 43 on the base substrate is overlapped, at least partially, with an orthographic projection of a second active layer between two gate electrodes in the second transistor T2 on the base substrate. The first shield electrode 43 is configured to shield an influence of data voltage jump on the second transistor T2, avoid data voltage jump from affecting a normal operation of the pixel drive circuit, and improve the display effect.

In an exemplary implementation mode, in one unit row, a first initial signal line 41, a first initial connection block 41-1, and a first shield electrode 43 may be connected with each other to form an integral structure.

In an exemplary implementation mode, the second initial signal line 42 may be in a shape of a straight line or a polyline in which a main portion extends along the first direction X, the second initial signal line 42 may be located on a side of the scan signal line away from the second electrode plate 32, and the second initial signal line 42 is configured to be connected with the first region of the seventh active layer through a seventh connection electrode formed subsequently.

In an exemplary implementation mode, a second initial connection block 42-1 may be provided on the second initial signal line 42. The second initial connection block 42-1 may be in a shape of a block (e.g., a rectangle), may be disposed on a side of the second initial signal line 42 close to the second electrode plate 32, and may be connected with the second initial signal line 42. The second initial signal line 42 is configured to be connected with the first region of the first active layer through a seventh connection electrode formed subsequently.

In an exemplary implementation mode, the second shield electrode 44 may be in a shape of a block (e.g., a rectangle), may be disposed on a side of the second initial signal line 42 close to the second electrode plate 32, and may be connected with the second initial signal line 42. An orthographic projection of the second shield electrode 44 on the base substrate is overlapped, at least partially, with an orthographic projection of a first active layer between two gate electrodes in the first transistor T1 on the base substrate. The second shield electrode 44 is configured to shield an influence of data voltage jump on the first transistor T1, avoid data voltage jump from affecting a normal operation of the pixel drive circuit, and improve the display effect.

In an exemplary implementation mode, in one unit row, a second initial signal line 42, a second initial connection block 42-1, and a second shield electrode 44 may be connected with each other to form an integral structure.

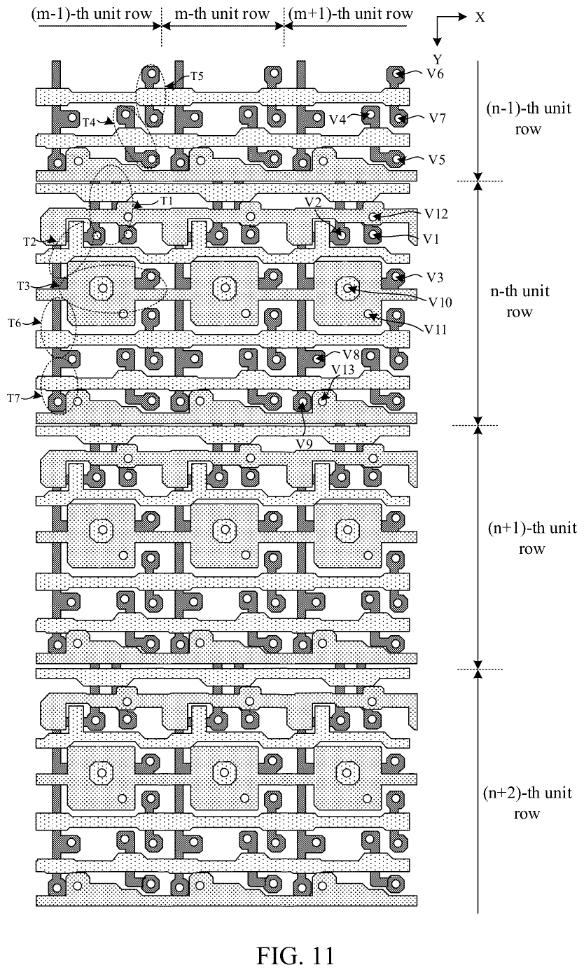

(4) A pattern of a fourth insulation layer is formed. In an exemplary implementation mode, forming the pattern of the fourth insulation layer may include: a fourth insulation thin film is deposited on the base substrate on which the aforementioned patterns are formed, and the fourth insulation thin film is patterned through a patterning process, to form a fourth insulation layer that covers the second conductive layer, wherein a plurality of vias are disposed on the fourth insulation layer, as shown in FIG. 11.

In an exemplary implementation mode, a plurality vias of each circuit unit include, at least, a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, and a thirteenth via V13.

In an exemplary implementation mode, an orthographic projection of the first via V1 on the base substrate is within a range of an orthographic projection of the first region of the first active layer on the base substrate. A fourth insulation layer, a third insulation layer, and a second insulation layer within the first via V1 are etched away to expose a surface of the first region of the first active layer, and the first via V1 is configured such that a sixth connection electrode formed subsequently is connected with the first region of the first active layer through this via.

In an exemplary implementation mode, an orthographic projection of the second via V2 on the base substrate is within a range of an orthographic projection of the second region of the first active layer (that is, the first region of the second active layer) on the base substrate. A fourth insulation layer, a third insulation layer, and a third insulation layer within the second via V2 are etched away to expose a surface of the second region of the first active layer (that is, the first region of the second active layer), and the second via V2 is configured such that a first connection electrode formed subsequently is connected with the second region of the first active layer (that is, the first region of the second active layer) through this via.

In an exemplary implementation mode, an orthographic projection of the third via V3 on the base substrate is within a range of an orthographic projection of the first region of the third active layer on the base substrate. A fourth insulation layer, a third insulation layer, and a second insulation layer within the third via V3 are etched away to expose a surface of the first region of the third active layer, and the third via V3 is configured such that a second connection line formed subsequently is connected with the first region of the third active layer through this via.

In an exemplary implementation mode, an orthographic projection of the fourth via V4 on the base substrate is within a range of an orthographic projection of the first region of the fourth active layer on the base substrate. A fourth insulation layer, a third insulation layer, and a second insulation layer within the fourth via V4 are etched away to expose a surface of the first region of the fourth active layer, and the fourth via V4 is configured such that a third connection line formed subsequently is connected with the first region of the fourth active layer through this via.

In an exemplary implementation mode, an orthographic projection of the fifth via V5 on the base substrate is within a range of an orthographic projection of the second region of the fourth active layer on the base substrate. A fourth insulation layer, a third insulation layer, and a second insulation layer within the fifth via V5 are etched away to expose a surface of the second region of the fourth active layer, and the fifth via V5 is configured such that a second connection electrode formed subsequently is connected with the second region of the fourth active layer through this via.

In an exemplary implementation mode, an orthographic projection of the sixth via V6 on the base substrate is within a range of an orthographic projection of the first region of the fifth active layer on the base substrate. A fourth insulation layer, a third insulation layer, and a second insulation layer within the sixth via V6 are etched away to expose a surface of the first region of the fifth active layer, and the sixth via V6 is configured such that a fourth connection electrode formed subsequently is connected with the first region of the fifth active layer through this via.

In an exemplary implementation mode, an orthographic projection of the seventh via V7 on the base substrate is within a range of an orthographic projection of the second region of the fifth active layer on the base substrate. A fourth insulation layer, a third insulation layer, and a second insulation layer within the seventh via V7 are etched away to expose a surface of the second region of the fifth active layer, and the seventh via V7 is configured such that a second connection electrode formed subsequently is connected with the second region of the fifth active layer through this via.

In an exemplary implementation mode, an orthographic projection of the eighth via V8 on the base substrate is within a range of an orthographic projection of the second region of the sixth active layer (i.e., the second region of the seventh active layer) on the base substrate. A fourth insulation layer, a third insulation layer, and a second insulation layer within the eighth via V8 are etched away to expose a surface of the second region of the sixth active layer (i.e., the second region of the seventh active layer), and the eighth via V8 is configured such that a fifth connection electrode formed subsequently is connected with the second region of the sixth active layer (i.e., the second region of the seventh active layer) through this via.

In an exemplary implementation mode, an orthographic projection of the ninth via V9 on the base substrate is within a range of an orthographic projection of the first region of the seventh active layer on the base substrate. A fourth insulation layer, a third insulation layer, and a second insulation layer within the ninth via V9 are etched away to expose a surface of the first region of the seventh active layer, and the ninth via V9 is configured such that a seventh connection electrode formed subsequently is connected with the first region of the seventh active layer through this via.

In an exemplary implementation mode, an orthographic projection of the tenth via V10 on the base substrate is located within a range of an orthographic projection of the opening 33 on the base substrate. A fourth insulation layer and a third insulation layer within the tenth via V10 are etched away to expose a surface of the first electrode plate 31, and the tenth via V10 is configured such that a first connection electrode formed subsequently is connected with the first electrode plate 31 through this via.

In an exemplary implementation mode, an orthographic projection of the eleventh via V11 on the base substrate is within a range of an orthographic projection of the second electrode plate 32 on the base substrate, a fourth insulation layer within the eleventh via V11 is etched away to expose a surface of the second electrode plate 32, and the eleventh via V11 is configured such that a fourth connection electrode formed subsequently is connected with the second electrode plate 32 through the via.

In an exemplary implementation mode, an orthographic projection of the twelfth via V12 on the base substrate is within a range of an orthographic projection of the first initial connection block 41-1 of the first initial signal line 41 on the base substrate. A fourth insulation layer within the twelfth via V12 is etched away to expose a surface of the first initial connection block 41-1, and the twelfth via V12 is configured such that a sixth connection electrode formed subsequently is connected with the first initial connection block 41-1 through this via.

In an exemplary implementation mode, an orthographic projection of the thirteenth via V13 on the base substrate is within a range of an orthographic projection of the second initial connection block 42-1 of the second initial signal line 42 on the base substrate. A fourth insulation layer within the thirteenth via V13 is etched away to expose a surface of the second initial connection block 42-1, and the thirteenth via V13 is configured such that a seventh connection electrode formed subsequently is connected with the second initial connection block 42-1 through this via.

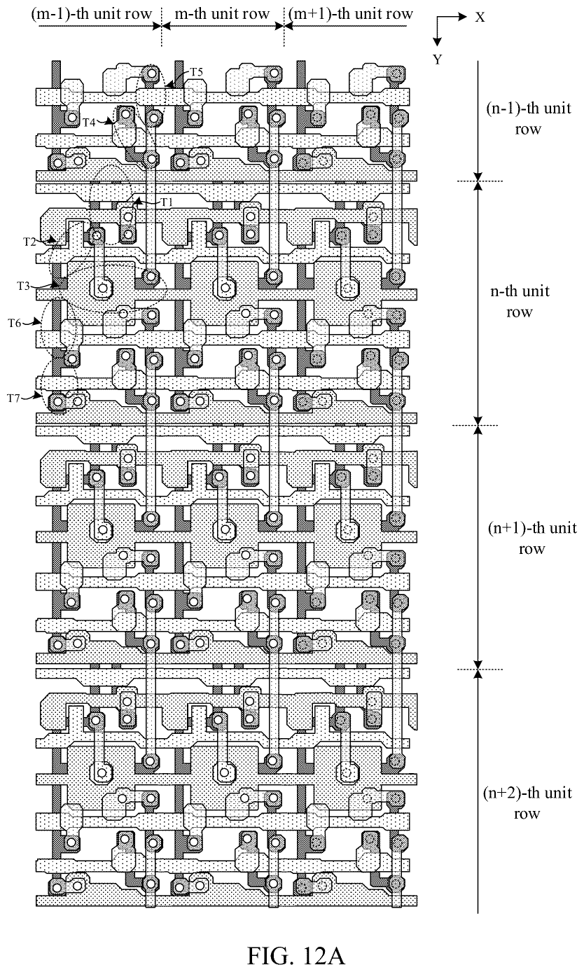

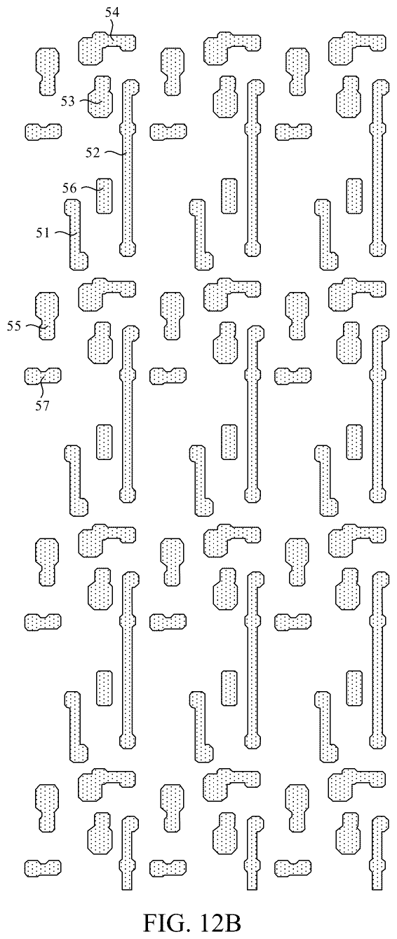

(5) A pattern of a third conductive layer is formed. In an exemplary implementation mode, forming the third conductive layer may include: a third conductive thin film is deposited on the base substrate on which the aforementioned patterns are formed, the third conductive thin film is patterned through a patterning process to form a third conductive layer disposed on the fourth insulation layer, as shown in FIG. 12A and FIG. 12B, wherein FIG. 12B is a schematic plan view of the third conductive layer in FIG. 12A. In an exemplary implementation mode, the third conductive layer may be referred to as a first source-drain metal (SD1) layer.

In an exemplary implementation mode, a third conductive layer of each circuit unit includes at least a first connection electrode 51, a second connection electrode 52, a third connection electrode 53, a fourth connection electrode 54, a fifth connection electrode 55, a sixth connection electrode 56, and a seventh connection electrode 57.

In an exemplary implementation mode, the first connection electrode 51 may be in a shape of a strip in which a main portion extends along the second direction Y, a first end of the first connection electrode 51 is connected with the second region of the first active layer (also the first region of the second active layer) through the second via V2, and a second end of the first connection electrode 51 is connected with the first electrode plate 31 through the tenth via V10. In an exemplary implementation mode, since the first electrode plate 31 also acts as a gate electrode of the third transistor T3, the first connection electrode 51 enables the second electrode of the first transistor T1, the first electrode of the second transistor T2, the gate electrode of the third transistor T3, and the first electrode plate 31 to have a same potential and form a first node N1 of the pixel drive circuit.

In an exemplary implementation mode, the second connection electrode 52 may be in a shape of a strip in which a main portion extends along the second direction Y, a first end of the second connection electrode 52 is connected with the first region of the third active layer through the third via V3, a second end of the second connection electrode 52 is connected with the second region of the fifth active layer through the seventh via V7, and a position between the first end and the second end is connected with the second region of the fourth active layer through the fifth via V5. In an exemplary implementation mode, the second connection electrode 52 enables the first electrode of the third transistor T3, the second electrode of the fourth transistor T4, and the second electrode of the fifth transistor T5 to have a same potential, forming a second node N2 of the pixel drive circuit.

In an exemplary implementation mode, since the fourth active layer and the fifth active layer of the pixel drive circuit in a current unit row are disposed in a circuit unit in a previous unit row, the second connection electrode 52 in the current unit row straddles in circuit units of two unit rows. A position of a via through which the second connection electrode 52 is connected with the second region of the fourth active layer and the second region of the fifth active layer is located in the circuit unit of the previous unit row, and a position of a via through which the second connection electrode 52 is connected with the first region of the third active layer is located in the circuit unit of the current unit row. For example, a position of a via through which a second connection electrode 52 of a pixel drive circuit in an n-th unit row is connected with a second region of a fourth active layer and a second region of a fifth active layer of the pixel drive circuit in the n-th unit row is located in a circuit unit of an (n−1)-th unit row, and a position of a via through which the second connection electrode 52 of the pixel drive circuit in the n-th unit row is connected with a first region of a third active layer of the pixel drive circuit in the n-th unit row is located in the circuit unit of the n-th unit row. For another example, a position of a via through which a fifth connection electrode 55 in an (n+1)-th unit row is connected with a second region of a fourth active layer and a second region of a fifth active layer of the pixel drive circuit in the (n+1)-th unit row is located in a circuit unit of an n-th unit row, and a position of a via through which the fifth connection electrode 55 in the (n+1)-th unit row is connected with a first region of a third active layer of the pixel drive circuit in the (n+1)-th unit row is located in a circuit unit of the (n+1)-th unit row.

In an exemplary implementation mode, an orthographic projection of the second connection electrode 52 (the second node N2 of the pixel drive circuit) on the base substrate is overlapped, at least partially, with orthographic projections of the first initial signal line 41 and the second initial signal line 42 on the base substrate, so that the first initial signal line 41 and the second initial signal line 42 having a constant potential may effectively stabilize a potential of the second node N2.

In an exemplary implementation mode, the orthographic projection of the second connection electrode 52 on the base substrate is overlapped, at least partially, with orthographic projections of the first scan signal line 21, the second scan signal line 22, the third scan signal line 23, and the fourth scan signal line 24 on the base substrate. Since a power supply signal output by a first power supply line is supplied to the second node N2 in a fifth stage of the pixel drive circuit drive timing, an influence of each scan line on the second node N2 may be reset, and light emission stability in a light emitting stage may be improved.

In an exemplary implementation mode, the third connection electrode 53 may be in a shape of a block (e.g., a rectangle), the third connection electrode 53 is connected with the first region of the fourth active layer through the fourth via V4, and the third connection electrode 53 is configured to be connected with a data signal line formed subsequently.

In an exemplary implementation mode, a shape of the fourth connection electrode 54 may be an “L” shape, a first end of the fourth connection electrode 54 is connected with the first region of the fifth active layer through the sixth via V6, and a second end of the fourth connection electrode 54 is connected with the second electrode plate 32 through the eleventh via V11, thereby achieving that the first electrode of the fifth transistor T5 and the second electrode plate 32 of the storage capacitor have a same potential. In an exemplary implementation mode, the fourth connection electrode 54 is configured to be connected with a first power supply line formed subsequently.

In an exemplary implementation mode, since the fifth active layer of the pixel drive circuit in the current unit row is disposed in the circuit unit in the previous unit row, the first end of the fourth connection electrode 54 in the current unit row is connected with a first region of a fifth active layer of a pixel drive circuit in a next unit row, and the second end of the fourth connection electrode 54 is connected with the second electrode plate 32 of the pixel drive circuit in the current unit row. For example, a fourth connection electrode 54 of a pixel drive circuit in an n-th unit row has a first end connected with a first region of a fifth active layer of a pixel drive circuit in an (n+1)-th unit row, and a second end connected with a second electrode plate 32 of the pixel drive circuit in the n-th unit row. For another example, a fourth connection electrode 54 in an (n+1)-th unit row has a first end connected with a first region of a fifth active layer of a pixel drive circuit in an (n+2)-th unit row, and a second end connected with a second electrode plate 32 of a pixel drive circuit in the (n+1)-th unit row.

In an exemplary implementation mode, the fifth connection electrode 55 may be in a shape of a block (e.g., a rectangle), the fifth connection electrode 55 is connected with the second region of the sixth active layer (also the second region of the seventh active layer) through the eighth via V8, and the sixth connection electrode 56 is configured to be connected with an anode connection electrode formed subsequently.

In an exemplary implementation mode, the sixth connection electrode 56 may be in a shape of a strip in which a main portion extends along the second direction Y, a first end of the sixth connection electrode 56 is connected with the first region of the first active layer through the first via V1, and a second end of the sixth connection electrode 56 is connected with the first initial connection block 41-1 through the twelfth via V12. In an exemplary implementation mode, since the first initial connection block 41-1 is connected with the first initial signal line 41, the sixth connection electrode 56 achieves a connection of the first initial signal line 41 with the first electrode of the first transistor T1, and the first initial signal line 41 may write a first initial signal to the first electrode of the first transistor T1.

In an exemplary implementation mode, the seventh connection electrode 57 may be in a shape of a strip extending along the first direction X, a first end of the seventh connection electrode 57 is connected with the first region of the seventh active layer through the ninth via V9, and a second end of the seventh connection electrode 57 is connected with the second initial connection block 42-1 through the thirteenth via V13. In an exemplary implementation mode, since the second initial connection block 42-1 is connected with the second initial signal line 42, the seventh connection electrode 57 achieves a connection of the second initial signal line 42 with the first electrode of the seventh transistor T7, and the second initial signal line 42 may write a second initial signal to the first electrode of the seventh transistor T7.

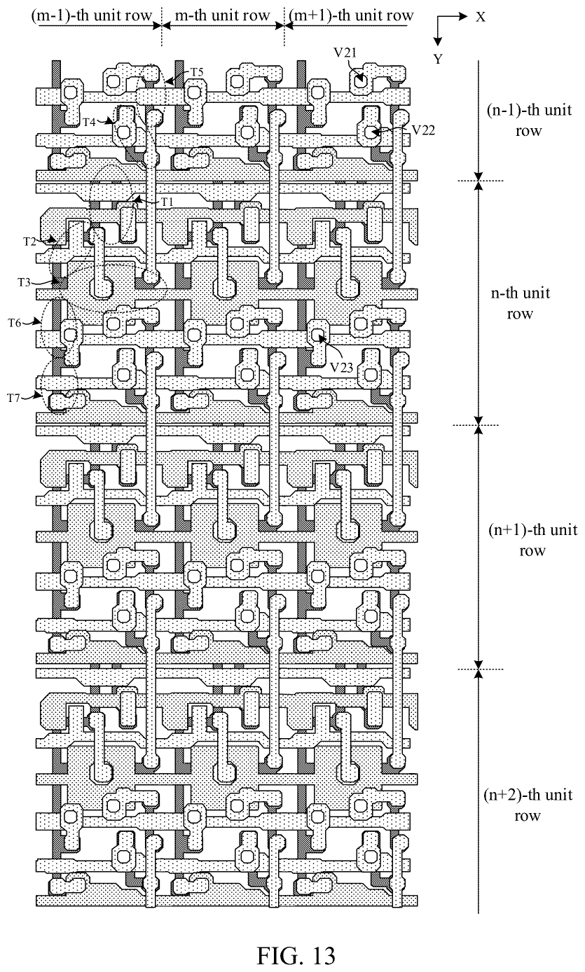

(6) A pattern of a first planarization layer is formed. In an exemplary implementation mode, forming the pattern of the first planarization layer may include: a first planarization thin film is coated on the base substrate on which the aforementioned patterns are formed, the first planarization thin film is patterned through a patterning process to form a first planarization layer covering the pattern of the third conductive layer, and the first planarization layer is provided with a plurality of vias, as shown in FIG. 13.

In an exemplary embodiment, the plurality of vias in each circuit unit at least includes a twenty-first via V21, a twenty-second via V22, and a twenty-third via V23.

In an exemplary implementation mode, an orthographic projection of the twenty-first via V21 on the base substrate is located within a range of an orthographic projection of the fourth connection electrode 54 on the base substrate, a first planarization layer within the twenty-first via V21 is etched away to expose a surface of the fourth connection electrode 54, and the twenty-first via V21 is configured such that a data signal line formed subsequently is connected with the fourth connection electrode 54 through this via.

In an exemplary implementation mode, an orthographic projection of the twenty-second via V22 on the base substrate is within a range of an orthographic projection of the third connection electrode 53 on the base substrate, a first planarization layer within the twenty-second via V22 is etched away to expose a surface of the third connection electrode 53, and the twenty-second via V22 is configured such that a power supply connection line formed subsequently is connected with the third connection electrode 53 through this via.

In an exemplary implementation mode, an orthographic projection of the twenty-third via V23 on the base substrate is within a range of an orthographic projection of the fifth connection electrode 55 on the base substrate, the first planarization layer within the twenty-third via V23 is etched away to expose a surface of the fifth connection electrode 55, and the twenty-third via V23 is configured such that an anode connection electrode formed subsequently is connected with the fifth connection electrode 55 through this via.

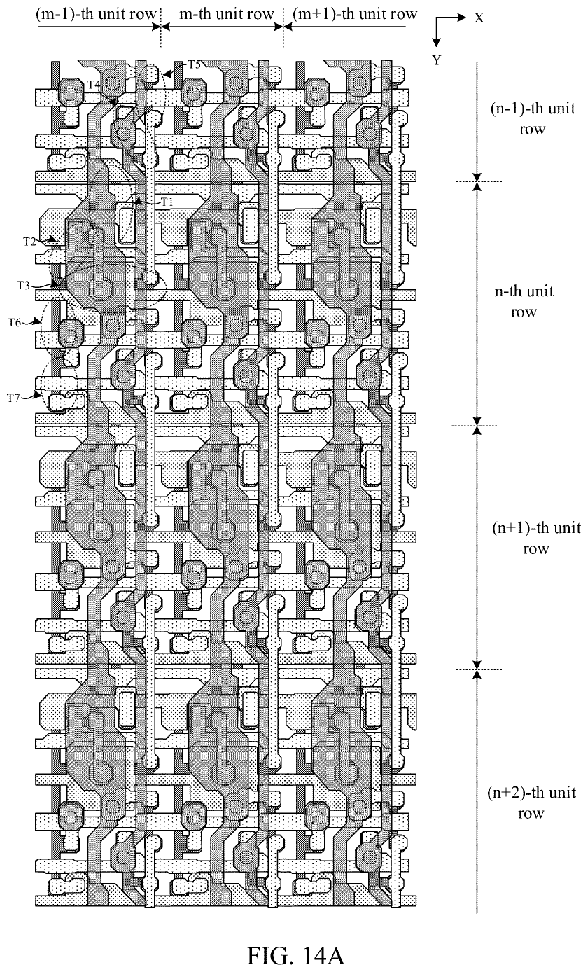

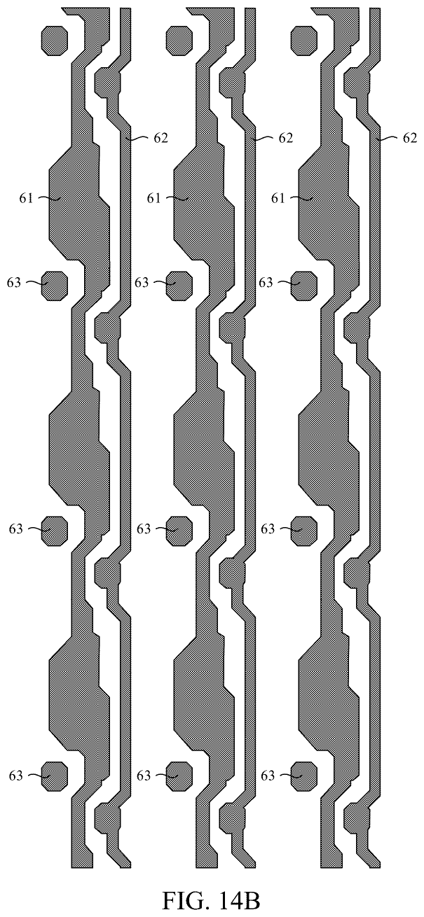

(7) A pattern of a fourth conductive layer is formed. In an exemplary implementation mode, forming the fourth conductive layer may include: a fourth conductive thin film is deposited on the base substrate on which the aforementioned patterns are formed, the fourth conductive thin film is patterned through a patterning process to form a fourth conductive layer disposed on the first planarization layer, as shown in FIG. 14A and FIG. 14B, wherein FIG. 14B is a schematic plan view of the fourth conductive layer in FIG. 14A. In an exemplary implementation mode, the fourth conductive layer may be referred to as a second source-drain metal (SD2) layer.

In an exemplary implementation mode, a fourth conductive layer of each circuit unit includes, at least, a first power supply line 61, a data signal line 62, and an anode connection electrode 63.

In an exemplary implementation mode, the first power supply line 61 may be in a shape of a straight line or a polyline in which a main portion extends along the second direction Y, and the first power supply line 61 is connected with the fourth connection electrode 54 through the twenty-first via V21. Since the fourth connection electrode 54 is connected with the first electrode of the fifth transistor T5 and the second electrode plate 32 of the storage capacitor respectively, it is achieved that the first power supply line 61 writes a power supply signal to the fifth transistor T5 and the second electrode plate 32 of the storage capacitor.

In an exemplary implementation mode, the first power supply line 61 may be a polyline with unequal widths, which may not only facilitate a layout of a pixel structure, but also reduce a parasitic capacitance between the first power supply line and a data signal line.

In an exemplary implementation mode, an orthographic projection of the first power supply line 61 on the base substrate is overlapped, at least partially, with an orthographic projection of the first connection electrode 51 on the base substrate, and the first power supply line 61 having a constant potential may effectively shield an influence of data voltage jump and other signals on the first node N1 in the pixel drive circuit, avoid the influence of the data voltage jump and other signals on a potential of the first node N1, and improve drive performance of the pixel drive circuit.

In an exemplary implementation mode, the data signal line 62 may be in a shape of a straight line or a polyline in which a main portion extends along the second direction Y, and the data signal line 62 is connected with the third connection electrode 53 through the twenty-second via V22. Since the third connection electrode 53 is connected with the first region of the fourth active layer through a via, a connection between the data signal line 62 and the first electrode of the fourth transistor T4 is achieved, and the data signal line 62 may write a data signal to the first electrode of the fourth transistor T4.

In an exemplary implementation mode, the anode connection electrode 63 may be in a shape of a block (e.g., a rectangle), the anode connection electrode 63 is connected with the fifth connection electrode 55 through the twenty-third via V23, and the anode connection electrode 63 is configured to be connected with an anode to be formed subsequently. Since the fifth connection electrode 55 is connected with the second region of the sixth active layer and a second region of the seventh active layer through a via, a connection between the anode to be formed subsequently and, the second electrode of the sixth transistor T6 and the second electrode of the seventh transistor T7 may be achieved, and the pixel drive circuit may drive a light emitting device to emit light.

A subsequent process may include forming a second planarization layer covering the pattern of the fourth conductive layer, the second planarization layer is provided with an anode via which exposes an anode connection electrode, the anode via is configured to enable an anode formed subsequently to be connected with the anode connection electrode through this via.

So far, a drive circuit layer has been prepared on the base substrate. In a plane parallel to the display substrate, the drive circuit layer may include a plurality of circuit units, each circuit unit may include a pixel drive circuit, and a scan signal line, a third scan signal line, a fourth scan signal line, a light emitting signal line, a first initial signal line, a second initial signal line, a first power supply line, and a data signal line which are connected with the pixel drive circuit. In a plane perpendicular to the display substrate, the drive circuit layer may include a first insulation layer, a semiconductor layer, a second insulation layer, a first conductive layer, a third insulation layer, a second conductive layer, a fourth insulation layer, a third conductive layer, a first planarization layer, a fourth conductive layer, and the second planarization layer which are disposed sequentially on the base substrate. The semiconductor layer may include, at least, active layers of the first transistor T1 to the seventh transistor T7. The first conductive layer may include, at least, the scan signal line, the third scan signal line, the fourth scan signal line, the light emitting signal line, and the first electrode plate of the storage capacitor. The second conductive layer may include, at least, the first initial signal line, the second initial signal line, and the second electrode plate of the storage capacitor. The third conductive layer may include, at least, a plurality of connection electrodes. The fourth conductive layer may include, at least, the first power supply line, the data signal line, and an anode connection electrode.

In an exemplary implementation mode, the base substrate may be a flexible base substrate, or a rigid base substrate. The rigid base substrate may include, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation mode, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the base substrate. The first inorganic material layer and the second inorganic material layer may also be referred to as barrier layers, and a material of the semiconductor layer may be amorphous silicon (a-si).

In an exemplary implementation mode, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, and the fourth insulation layer may be made of any one or more of Silicon Oxide (SiOx), Silicon Nitride (SiNx), and Silicon Oxynitride (SiON), and may be a single layer, a multi-layer, or a composite layer. The first planarization layer and the second planarization layer may be made of an organic material, such as resin.

In an exemplary implementation mode, after the drive circuit layer has been prepared, a light emitting structure layer may be prepared on the drive circuit layer, and then an encapsulation structure layer may be prepared on the light emitting structure layer, which will not be repeated here.

A 7T1C structure is adopted for a pixel drive circuit in a display substrate, and a pixel drive circuit of each circuit unit is connected with 4 scan signal lines (a first scan signal line to a fourth scan signal line) and 2 light emitting signal lines (a first light emitting signal line and a second light emitting signal line). More signal lines not only increase an occupied area, but also require corresponding transistors disposed in a staggered manner, which increases complexity of the structure of the pixel drive circuit, makes it difficult to reduce a dimension of the circuit unit, and it is difficult to improve a resolution (Pixels Per Inch (PPI)) of a display apparatus. Moreover, more scan signal lines and light emitting signal lines increase a quantity of corresponding gate drive circuits in a bezel region, which increases the gate drive circuits and an occupied area, and is not conducive to achieving a narrow bezel.

According to the display substrate provided in the exemplary embodiment of the present disclosure, by disposing pixel drive circuits in two adjacent unit rows in a staggered manner and signal borrowing, the fifth transistor T5 of the pixel drive circuit in the current unit row and the sixth transistor T6 of the pixel drive circuit in the previous unit row share a same light emitting signal line, and turn-on and turn-off of the fifth transistor T5 of the pixel drive circuit in the current unit row and the sixth transistor T6 of the pixel drive circuit in the previous unit row are controlled by the same light emitting signal line. The fourth transistor T4 of the pixel drive circuit in the current unit row and the seventh transistor T7 of the pixel drive circuit in the previous unit row share a same scan signal line, and turn-on and turn-off of the fourth transistor T4 of the pixel drive circuit in the current unit row and the seventh transistor T7 of the pixel drive circuit in the previous unit row are controlled by the same scan signal line. A quantity of signal lines is effectively reduced, an additional demand for space by more signal lines is avoided, a layout of the pixel drive circuit is optimized, a dimension of a circuit unit is effectively reduced, and a resolution of a display apparatus is effectively improved.

According to the display substrate in the present disclosure, the sixth transistor T6 of the pixel drive circuit in the previous unit row and the fifth transistor T5 of the pixel drive circuit in the current unit row are disposed in the circuit unit in the previous unit row. The fifth transistor T5 and the sixth transistor T6 are simultaneously connected with a light emitting signal line in the previous unit row. That is, the fifth transistor T5 of the pixel drive circuit in the current unit row and the sixth transistor T6 of the pixel drive circuit in the previous unit row share the same light emitting signal line. The light emitting signal line acts as a second light emitting signal line of the pixel drive circuit in the previous unit row, and also acts as a first light emitting signal line of the pixel drive circuit in the previous unit row, thereby achieving the fifth transistor T5 in the current unit row borrowing a control signal of the sixth transistor T6 in the previous unit row. Compared with an existing structure in which a first light emitting signal line controlling the fifth transistor T5 and a second light emitting signal line controlling the sixth transistor T6 are provided in each unit row, in the present disclosure, only one light emitting signal line is provided in a unit row through a staggered arrangement and signal borrowing of transistors in adjacent unit rows, which not only reduces a quantity of signal lines, reduces an occupied area, but also reduces complexity of a structure of the pixel drive circuit, may effectively reduce a dimension of a circuit unit, and may effectively improve a resolution of a display apparatus.

In the present disclosure, the fifth transistor and the sixth transistor are controlled separately, the fifth transistor T5 in the current unit row is connected with a light emitting signal line in the previous unit row, the sixth transistor T6 is connected with a light emitting signal line in the current unit row, and light emitting signal lines in two unit rows adjust a duty of Pulse Width Modulation (PWM) together, so that pulse width modulation with higher ultra-high frequency accuracy, duty compensation of a light emitting signal, low grayscale compensation, and improvement of an afterimage may be achieved.

According to the display substrate in the present disclosure, the seventh transistor T7 of the pixel drive circuit in the previous unit row and the fourth transistor T4 of the pixel drive circuit in the current unit row are disposed in the circuit unit in the previous unit row. The fourth transistor T4 and the seventh transistor T7 are simultaneously connected with a light emitting signal line in the previous unit row. That is, the fourth transistor T4 of the pixel drive circuit in the current unit row and the seventh transistor T7 of the pixel drive circuit in the previous unit row share the same light emitting signal line. The light emitting signal line acts as a second scan signal line of the pixel drive circuit in the previous unit row, and also acts as a first scan signal line of the pixel drive circuit in the previous unit row, thereby achieving the fourth transistor T4 in the current unit row borrowing a control signal of the seventh transistor T7 in the previous unit row. Compared with an existing structure in which a first scan signal line controlling the fourth transistor T4 and a second scan signal line controlling the seventh transistor T7 are provided in each unit row, in the present disclosure, only one scan signal line is provided in a unit row through a staggered arrangement and signal borrowing of transistors in adjacent unit rows, which not only reduces a quantity of signal lines, reduces an occupied area, but also reduces complexity of a structure of the pixel drive circuit, may effectively reduce a dimension of a circuit unit, and may effectively improve a resolution of a display apparatus.

In the present disclosure, by reducing quantities of light emitting signal lines and scan signal lines in unit rows, a space utilization rate is optimized, and a layout is more reasonable, a distance between various nodes in the pixel drive circuit and a distance between each node and the signal lines may be ensured, which may effectively avoid bad crosstalk, effectively improve display quality of the display apparatus, effectively improve a product yield, and reduce a production cost.

In the present disclosure, by reducing quantities of light emitting signal lines and scan signal lines in unit rows, a quantity of corresponding gate drive circuits in a bezel region may be reduced by multiple times, which effectively reduces an occupied area of the gate drive circuits, is beneficial to achieve a narrow bezel, and improve product advantages.

In the present disclosure, by providing the first power supply line to cover the first connection electrode, an influence of data voltage jump and other signals on the first node in the pixel drive circuit may be effectively shielded, thus avoiding an influence of data voltage jump and other signals on the potential of the first node, and effectively avoiding deterioration of crosstalk. The preparation process in the present disclosure may be compatible well with an existing preparation process, is simple in process implementation, is easy to implement, and has a high production efficiency, a low production cost, and a high yield.

The aforementioned structure shown in the present disclosure and the preparation process thereof are merely exemplary description. In an exemplary implementation mode, corresponding structures may be changed and patterning processes may be added or reduced according to actual needs, which is not limited here in the present disclosure.

In an exemplary implementation mode, the display substrate according to the present disclosure may be applied to a display apparatus with a pixel drive circuit, such as an OLED, quantum dot display (QLED), light emitting diode display (Micro LED or Mini LED), or Quantum Dot Light Emitting Diode display (QDLED), which is not limited here in the present disclosure.

The present disclosure also provides a drive method of a display substrate for driving the display substrate according to the aforementioned embodiments. In an exemplary implementation mode, the display substrate includes a plurality of circuit units constituting a plurality of unit rows and a plurality of unit columns. At least one circuit unit includes, at least, a pixel drive circuit and a light emitting signal line, the pixel drive circuit is configured to output a drive current to a connected light emitting device, and the light emitting signal line is configured to provide a light emitting control signal to the pixel drive circuit. In at least one circuit unit, the pixel drive circuit includes, at least, a third transistor acting as a drive transistor, a fifth transistor acting as a first light emitting control transistor, and a sixth transistor acting as a second light emitting control transistor. A first electrode of the fifth transistor is connected with a first power supply line, a second electrode of the fifth transistor is connected with a first electrode of the third transistor, a first electrode of the sixth transistor is connected with a second electrode of the third transistor, and a second electrode of the sixth transistor is connected with the light emitting device. The drive method includes, at least, a light emitting stage in which, in at least one pixel drive circuit in at least one unit row, turn-on and turn-off of the fifth transistor is controlled by the light emitting signal line in a previous unit row, and turn-on and turn-off of the sixth transistor is controlled by the light emitting signal line in a current unit row.

In an exemplary implementation mode, at least one circuit unit further includes a scan signal line configured to provide a scan signal to the pixel drive circuit. The pixel drive circuit further includes a fourth transistor acting as a data writing transistor and a seventh transistor acting as a second initialization transistor, a first electrode of the fourth transistor is connected with a data signal line, a second electrode of the fourth transistor is connected with a first electrode of the third transistor, a first electrode of the seventh transistor is connected with a second initial signal line, and a second electrode of the seventh transistor is connected with a second electrode of the sixth transistor. The drive method further includes a data writing stage and a reset stage. In at least one pixel drive circuit in at least one unit row, turn-on and turn-off of the fourth transistor is controlled by the scan signal line in a previous unit row in the data writing stage, and turn-on and turn-off of the seventh transistor is controlled by the scan signal line in a current unit row in the reset stage.

A display apparatus which includes the aforementioned display substrate is also provided in the present disclosure. The display apparatus may be any product or component with a display function, such as a mobile phone, a tablet computer, a television, a display, a laptop computer, a digital photo frame, and a navigator, which is not limited in the embodiments of the present disclosure.

Although implementation modes disclosed in the present disclosure are as above, it should be noted that the above implementation modes are exemplary only rather than restrictive. Therefore, the present disclosure is not limited to what is specifically shown and described herein. Various modifications, substitutions, or omissions may be made in forms and details of implementation without departing from the scope of the present disclosure.

1. A display substrate, comprising a plurality of circuit units constituting a plurality of unit rows and a plurality of unit columns; at least one circuit unit comprises, at least, a pixel drive circuit and a light emitting signal line, wherein the pixel drive circuit is configured to output a drive current to a connected light emitting device, and the light emitting signal line is configured to provide a light emitting control signal to the pixel drive circuit; in at least one circuit unit, the pixel drive circuit comprises, at least, a third transistor acting as a drive transistor, a fifth transistor acting as a first light emitting control transistor, and a sixth transistor acting as a second light emitting control transistor; wherein a first electrode of the fifth transistor is connected with a first power supply line, a second electrode of the fifth transistor is connected with a first electrode of the third transistor, a first electrode of the sixth transistor is connected with a second electrode of the third transistor, and a second electrode of the sixth transistor is connected with the light emitting device; in at least one pixel drive circuit of at least one unit row, the fifth transistor is connected with the light emitting signal line in a previous unit row, and the sixth transistor is connected with the light emitting signal line in a current unit row.

2. The display substrate according to claim 1, wherein in at least one pixel drive circuit, the fifth transistor and the sixth transistor are disposed on both sides of the third transistor in a unit column direction, respectively.

3. The display substrate according to claim 2, wherein the fifth transistor comprises, at least, a fifth active layer, and the sixth transistor comprises, at least, a sixth active layer; in at least one pixel drive circuit of at least one unit row, the fifth active layer is disposed in a circuit unit of the previous unit row, and the sixth active layer is disposed in a circuit unit of the current unit row.

4. The display substrate according to claim 3, wherein in at least one pixel drive circuit of at least one unit row, the fifth active layer is disposed on a side of the sixth active layer of the pixel drive circuit in the previous unit row in a unit row direction.

5. The display substrate according to claim 3, wherein the pixel drive circuit further comprises a storage capacitor and a power supply connection electrode, the storage capacitor comprises a first electrode plate and a second electrode plate, an orthographic projection of the first electrode plate on a plane of the display substrate is overlapped, at least partially, with an orthographic projection of the second electrode plate on the plane of the display substrate; in at least one pixel drive circuit in at least one unit row, a first end of the power supply connection electrode is connected with a first region of the fifth active layer of the pixel drive circuit in a next unit row, and a second end of the power supply connection electrode is connected with the second electrode plate of the pixel drive circuit in the current unit row.

6. The display substrate according to claim 1, wherein at least one circuit unit further comprises a scan signal line configured to provide a scan signal to the pixel drive circuit; the pixel drive circuit further comprises a fourth transistor acting as a data writing transistor and a seventh transistor acting as a second initialization transistor, wherein a first electrode of the fourth transistor is connected with a data signal line, a second electrode of the fourth transistor is connected with a first electrode of the third transistor, a first electrode of the seventh transistor is connected with a second initial signal line, and a second electrode of the seventh transistor is connected with a second electrode of the sixth transistor; in at least one pixel drive circuit of at least one unit row, the fourth transistor is connected with the scan signal line in the previous unit row, and the seventh transistor is connected with the scan signal line in the current unit row.

7. The display substrate according to claim 6, wherein in at least one pixel drive circuit, the fourth transistor and the seventh transistor are disposed on both sides of the third transistor in a unit column direction, respectively.

8. The display substrate according to claim 7, wherein the fourth transistor comprises, at least, a fourth active layer, and the seventh transistor comprises, at least, a seventh active layer; in at least one pixel drive circuit of at least one unit row, the fourth active layer is disposed in a circuit unit in the previous unit row, and the seventh active layer is disposed in a circuit unit of the current unit row.

9. The display substrate according to claim 8, wherein in at least one pixel drive circuit of at least one unit row, the fourth active layer is disposed on a side of the seventh active layer of the pixel drive circuit in the previous unit row in a unit row direction.

10. The display substrate according to claim 1, wherein the pixel drive circuit further comprises a first transistor acting as a first initialization transistor, a second transistor acting as a compensation transistor, a fourth transistor acting as a data writing transistor, and a seventh transistor acting as a second initialization transistor, wherein a first electrode of the first transistor is connected with a first initial signal line, a first electrode of the fourth transistor connected with a data signal line, a first electrode of the seventh transistor is connected with a second initial signal line, a second electrode of the first transistor and a first electrode of the second transistor are connected with a gate electrode of the third transistor through a first node electrode, and a first electrode of the third transistor, a second electrode of the fourth transistor, and a second electrode of the fifth transistor are connected with each other through a second node electrode.

11. The display substrate according to claim 10, wherein an orthographic projection of the first power supply line on a plane of the display substrate is overlapped, at least partially, with an orthographic projection of the first node electrode on the plane of the display substrate.

12. The display substrate according to claim 10, wherein an orthographic projection of the second node electrode on a plane of the display substrate is overlapped, at least partially, with an orthographic projection of the first initial signal line on the plane of the display substrate, and/or, the orthographic projection of the second node electrode on the plane of the display substrate is overlapped, at least partially, with an orthographic projection of the second initial signal line on the plane of the display substrate.

13. The display substrate according to claim 10, wherein a gate electrode of the first transistor is connected with a fourth scan signal line, and an orthographic projection of the second node electrode on a plane of the display substrate is overlapped, at least partially, with an orthographic projection of the fourth scan signal line on the plane of the display substrate.

14. The display substrate according to claim 10, wherein a gate electrode of the second transistor is connected with a third scan signal line, and an orthographic projection of the second node electrode on a plane of the display substrate is overlapped, at least partially, with an orthographic projection of the third scan signal line on the plane of the display substrate.

15. The display substrate according to claim 10, wherein the first initial signal line is connected with a first shield electrode, an orthographic projection of the first shield electrode on a plane of the display substrate is overlapped, at least partially, with an orthographic projection of a node between two gate electrodes in the second transistor on the plane of the display substrate.

16. The display substrate according to claim 10, wherein the second initial signal line is connected with a second shield electrode, an orthographic projection of the second shield electrode on a plane of the display substrate is overlapped, at least partially, with an orthographic projection of a node between two gate electrodes in the first transistor on the plane of the display substrate.

17. A display apparatus, comprising a display substrate according to claim 1.

18. A drive method of a display substrate, wherein the display substrate comprises a plurality of circuit units constituting a plurality of unit rows and a plurality of unit columns; at least one circuit unit comprises, at least, a pixel drive circuit and a light emitting signal line, wherein the pixel drive circuit is configured to output a drive current to a connected light emitting device, and the light emitting signal line is configured to provide a light emitting control signal to the pixel drive circuit; in at least one circuit unit, the pixel drive circuit comprises, at least, a third transistor acting as a drive transistor, a fifth transistor acting as a first light emitting control transistor, and a sixth transistor acting as a second light emitting control transistor; a first electrode of the fifth transistor is connected with a first power supply line, a second electrode of the fifth transistor is connected with a first electrode of the third transistor, a first electrode of the sixth transistor is connected with a second electrode of the third transistor, and a second electrode of the sixth transistor is connected with the light emitting device; the drive method comprises, at least, a light emitting stage in which, in at least one pixel drive circuit of at least one unit row, turn-on and turn-off of the fifth transistor is controlled by the light emitting signal line in a previous unit row, and turn-on and turn-off of the sixth transistor is controlled by the light emitting signal line in a current unit row.

19. The drive method according to claim 18, wherein at least one circuit unit further comprises a scan signal line configured to provide a scan signal to the pixel drive circuit; the pixel drive circuit further comprises a fourth transistor acting as a data writing transistor and a seventh transistor acting as a second initialization transistor, a first electrode of the fourth transistor is connected with a data signal line, a second electrode of the fourth transistor is connected with a first electrode of the third transistor, a first electrode of the seventh transistor is connected with a second initial signal line, and a second electrode of the seventh transistor is connected with a second electrode of the sixth transistor; the drive method further comprises a data writing stage and a reset stage; in at least one pixel drive circuit of at least one unit row, turn-on and turn-off of the fourth transistor is controlled by the scan signal line in the previous unit row in the data writing stage, and turn-on and turn-off of the seventh transistor is controlled by the scan signal line in the current unit row in the reset stage.

20. The display substrate according to claim 2, wherein the pixel drive circuit further comprises a first transistor acting as a first initialization transistor, a second transistor acting as a compensation transistor, a fourth transistor acting as a data writing transistor, and a seventh transistor acting as a second initialization transistor, wherein a first electrode of the first transistor is connected with a first initial signal line, a first electrode of the fourth transistor connected with a data signal line, a first electrode of the seventh transistor is connected with a second initial signal line, a second electrode of the first transistor and a first electrode of the second transistor are connected with a gate electrode of the third transistor through a first node electrode, and a first electrode of the third transistor, a second electrode of the fourth transistor, and a second electrode of the fifth transistor are connected with each other through a second node electrode.
